(19) United States
(12) Patent Application Publication
(10) Pub. No.: US 2026/0271520 A1
(43) Pub. Date: Sep. 10, 2026

(54) DISPLAY DEVICE AND ELECTRONIC DEVICE

(71) Applicant: Samsung Display Co., Ltd., Yongin-si (KR)

(72) Inventors: Dong Hee SHIN, Yongin-si (KR); Kyung Ho KIM, Yongin-si (KR); Jung Hwan HWANG, Yongin-si (KR)

(21) Appl. No.: 19/332,409

(22) Filed: Sep. 18, 2025

(30) Foreign Application Priority Data
Mar. 6, 2025 (KR) 10-2025-0028941
May 2, 2025 (KR) 10-2025-0058262

(51) Int. Cl. H10K 59/121; G09G 3/3233; G09G 3/3266

(52) U.S. Cl. CPC H10K 59/1213; G09G 3/3233; G09G 3/3266; G09G 2300/0426; G09G 2300/0819; G09G 2300/0852; G09G 2300/0861; G09G 2310/0286

(57) ABSTRACT

A display device according to an embodiment includes a substrate, a first driving transistor arranged on the substrate, including a first active layer and a first gate electrode, a first insulating layer arranged on the first driving transistor, a second driving transistor arranged on the first insulating layer, including a second active layer electrically connected to the first active layer and a second gate electrode electrically connected to the first gate electrode, a second insulating layer arranged on the second driving transistor, and a light emitting element arranged on the second insulating layer.

### CROSS-REFERENCE TO RELATED APPLICATION

The present application claims priority to and the benefit of Korean Patent Application No. 10-2025-0028941, filed on Mar. 6, 2025, and Korean Patent Application No. 10-2025-0058262, filed on May 2, 2025, in the Korean Intellectual Property Office, the entire disclosure of each of which is incorporated herein by reference.

### BACKGROUND

### 1. Field

Aspects of some embodiments of the present disclosure relate to a display device and an electronic device capable of displaying an image.

### 2. Description of the Related Art

As the information society develops, the demand for display devices and electronic devices capable of displaying images is increasing in various forms. Accordingly, various forms of display devices and electronic devices including pixels for displaying images are being developed. The display device may be provided alone or may be included in an electronic device and used as a display screen of the electronic device.

The above information disclosed in this Background section is only for enhancement of understanding of the background and therefore the information discussed in this Background section does not necessarily constitute prior art.

### SUMMARY

Aspects of some embodiments of the present disclosure include a display device and an electronic device capable of relatively improving the operating characteristics of a driving transistor.

However, aspects of embodiments according to the present disclosure are not restricted to those specifically articulated set forth herein. The above and other aspects of embodiments according to the present disclosure will become more apparent to one of ordinary skill in the art to which the present disclosure pertains by referencing the detailed description of the present disclosure given below.

According to some embodiments of the present disclosure, there is provided a display device including a substrate, a first driving transistor arranged on the substrate, including a first active layer and a first gate electrode, a first insulating layer arranged on the first driving transistor, a second driving transistor arranged on the first insulating layer, including a second active layer electrically connected to the first active layer and a second gate electrode electrically connected to the first gate electrode, a second insulating layer arranged on the second driving transistor, and a light emitting element arranged on the second insulating layer.

According to some embodiments, the first active layer and the second active layer may overlap each other in a thickness direction of the substrate.

According to some embodiments, the first driving transistor may further include a first bottom electrode arranged between the substrate and the first active layer and overlapping a channel region of the first active layer, and the first bottom electrode may be electrically connected to a source region of the second active layer.

According to some embodiments, the second driving transistor may further include a second bottom electrode arranged between the first insulating layer and the second active layer and overlapping a channel region of the second active layer, and the second bottom electrode may be electrically connected to a source region of the second active layer.

According to some embodiments, the second driving transistor may further include a second bottom electrode arranged between the first insulating layer and the second active layer and overlapping a channel region of the second active layer, and the second bottom electrode may be electrically connected to the second gate electrode.

According to some embodiments, the display device may further include a connection electrode electrically connecting the first active layer and the second active layer.

According to some embodiments, the connection electrode may include a lower electrode arranged on the first insulating layer and electrically connected to a source region of the first active layer, and an upper electrode arranged on the second insulating layer and electrically connected to a drain region of the second active layer and the lower electrode.

According to some embodiments, the display device may further include a first switching transistor arranged on the substrate, and including an active layer arranged on a same layer as the first active layer and a gate electrode arranged in a same layer as the first gate electrode.

According to some embodiments, the display device may further include capacitor electrodes arranged on the first switching transistor and overlapping each other.

According to some embodiments, the display device may further include a second switching transistor arranged on the substrate, and including an active layer arranged in a same layer as the first active layer and a gate electrode arranged in a same layer as the first gate electrode, and a third switching transistor arranged on the first insulating layer, and including an active layer arranged in a same layer as the second active layer and a gate electrode arranged in a same layer as the second gate electrode, and the second switching transistor and the third switching transistor may overlap each other in a thickness direction of the substrate.

According to some embodiments, each of the first active layer and the second active layer may include an oxide semiconductor.

According to some embodiments, the display device may further include a pixel arranged in a display area on the substrate, and including the first driving transistor, the second driving transistor, and the light emitting element, and a gate driver arranged in a non-display area on the substrate, and electrically connected to the pixel.

According to some embodiments, the gate driver may include a lower transistor including an active layer arranged in a same layer as the first active layer and a gate electrode arranged in a same layer as the first gate electrode, and an upper transistor including an active layer arranged in a same layer as the second active layer and a gate electrode arranged in a same layer as the second gate electrode.

According to some embodiments, the lower transistor and the upper transistor may overlap each other in a thickness direction of the substrate.

According to some embodiments of the present disclosure, there is provided an electronic device including a display module including a display panel, and a processor for transmitting an image data signal to the display module. The display panel may include a substrate, a first driving transistor arranged on the substrate, including a first active layer and a first gate electrode, a first insulating layer arranged on the first driving transistor, a second driving transistor arranged on the first insulating layer, including a second active layer electrically connected to the first active layer and a second gate electrode electrically connected to the first gate electrode, a second insulating layer arranged on the second driving transistor, and a light emitting element arranged on the second insulating layer.

According to some embodiments, the first active layer and the second active layer may overlap each other in a thickness direction of the substrate.

According to some embodiments, the first driving transistor may further include a first bottom electrode arranged between the substrate and the first active layer and overlapping a channel region of the first active layer, and the first bottom electrode may be electrically connected to a source region of the second active layer.

According to some embodiments, the second driving transistor may further include a second bottom electrode arranged between the first insulating layer and the second active layer and overlapping a channel region of the second active layer, and the second bottom electrode may be electrically connected to a source region of the second active layer or to the second gate electrode.

According to some embodiments, the display panel may further include a first switching transistor arranged on the substrate, including an active layer arranged in a same layer as the first active layer and a gate electrode arranged in a same layer as the first gate electrode, and capacitor electrodes arranged on the first switching transistor and overlapping each other.

According to some embodiments, the display panel may further include a second switching transistor arranged on the substrate, and including an active layer arranged in a same layer as the first active layer and a gate electrode arranged in a same layer as the first gate electrode, and a third switching transistor arranged on the first insulating layer, and including an active layer arranged in a same layer as the second active layer and a gate electrode arranged in a same layer as the second gate electrode, and the second switching transistor and the third switching transistor may overlap each other in a thickness direction of the substrate.

The display device and the electronic device according to some embodiments may include a dual-structured driving transistor including a first driving transistor and a second driving transistor sequentially arranged on a substrate. According to some embodiments, the channel length and the subthreshold slope of the driving transistor may be increased or secured to relatively improve the operating characteristics of the driving transistor. Accordingly, the low-grayscale expressiveness of the display device and the electronic device may be increased, and the design structure of the panel circuit layer may be relatively improved or optimized.

However, the characteristics of embodiments according to the present disclosure are not limited to those described above and various other characteristics are incorporated herein.

### BRIEF DESCRIPTION OF THE DRAWINGS

FIG. 1 is a plan view illustrating a display device according to some embodiments.

FIG. 2 is a plan view illustrating a display panel of FIG. 1.

FIG. 3 is a circuit diagram illustrating a pixel according to some embodiments.

FIG. 4 is a circuit diagram illustrating a pixel according to some embodiments.

FIG. 5 is a diagram schematically illustrating a gate driver according to some embodiments.

FIG. 6 is a diagram schematically illustrating a stage of a gate driver according to some embodiments.

FIG. 7 is a cross-sectional view illustrating a portion of a display panel according to some embodiments.

FIG. 8 is a cross-sectional view illustrating a portion of a display panel according to some embodiments.

FIG. 9 is a plan view schematically illustrating lower transistors and upper transistors according to some embodiments.

FIG. 10 is a plan view illustrating lower patterns including lower transistors of FIG. 9.

FIG. 11 is a plan view illustrating upper patterns including upper transistors of FIG. 9.

FIG. 12 is a plan view schematically illustrating lower transistors and upper transistors according to some embodiments.

FIG. 13 is a plan view illustrating lower patterns including lower transistors of FIG. 12.

FIG. 14 is a plan view illustrating upper patterns including upper transistors of FIG. 12.

FIG. 15 is a plan view schematically illustrating lower transistors and upper transistors according to some embodiments.

FIG. 16 is a plan view illustrating lower patterns including lower transistors of FIG. 15.

FIG. 17 is a plan view illustrating upper patterns including upper transistors of FIG. 15.

FIG. 18 is a cross-sectional view illustrating a portion of a display panel according to some embodiments.

FIG. 19 is a block diagram of an electronic device according to some embodiments.

FIG. 20 is schematic diagrams of an electronic device according to some embodiments.

### DETAILED DESCRIPTION

The present invention will now be described more fully hereinafter with reference to the accompanying drawings, in which aspects of some embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art.

It will also be understood that when an element or a layer includes referred to as being “on” another element or layer, it can be directly on the other element or layer, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present invention. Similarly, the second element could also be termed the first element.

Features of each of various embodiments of the present disclosure may be partially or entirely combined with each other and may technically variously interwork with each other, and respective embodiments may be implemented independently of each other or may be implemented together in association with each other.

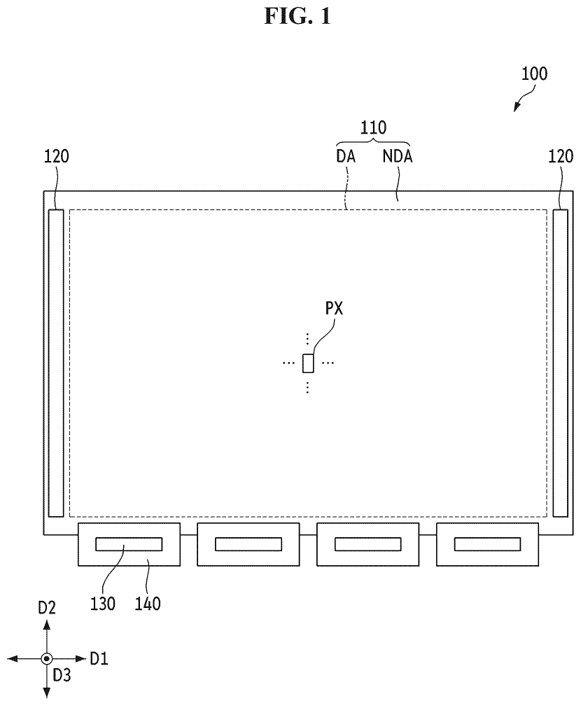

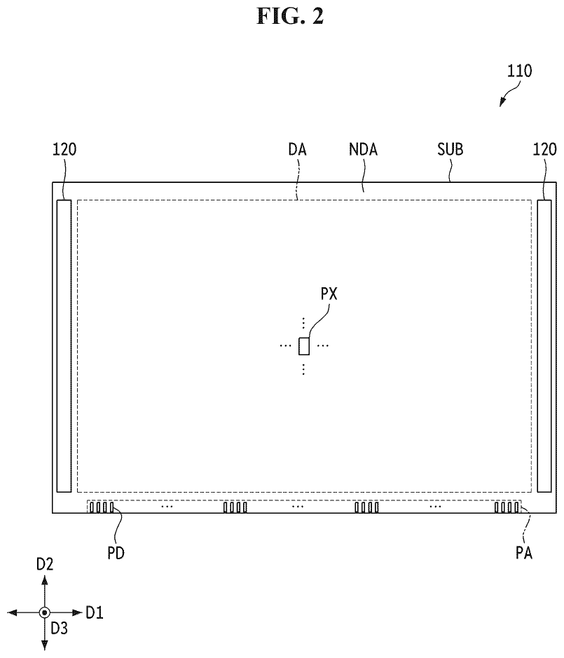

FIG. 1 is a plan view illustrating a display device according to some embodiments. FIG. 2 is a plan view illustrating a display panel of FIG. 1.

Referring to FIGS. 1 and 2, the display device 100 is a device that displays a moving image or a still image, and may be included in a variety of electronic devices such as televisions, laptops, monitors, billboards, the internet of things (IOT), and other electronic devices such as mobile phones, smart phones, tablet personal computers, and portable electronic devices such as smart watches, watch phones, mobile communication terminals, notebooks, e-books, portable multimedia players (PMP), navigation systems, ultra mobile PC (UMPC), and the like, as well as televisions, laptops, monitors, billboards, and the like, and may be used as display screens. Further, the display device 100 may be included in an electronic device such as a virtual reality (VR) device or an augmented reality (AR) device. According to some embodiments, an electronic device including the display device 100 may further include a display device storage portion in which the display device 100 is stored, and/or a case or cover for protecting the display device 100.

According to some embodiments, the display device 100 may be a light emitting display device such as an organic light emitting display device including an organic light emitting diode, a quantum dot light emitting display device including a quantum dot light emitting layer, an inorganic light emitting display device including an inorganic semiconductor, or a micro light emitting display device including a micro light emitting diode, such as a micro or nano light emitting diode (micro LED or nano LED) but is not limited thereto. For example, the display device 100 may be a type of display device other than the light emitting display device. Hereinafter, aspects embodiments in which a display device 100 is a light emitting display device (e.g., an organic light-emitting display device) are described in more detail, but embodiments according to the present disclosure are not limited thereto.

The display device 100 may include a display panel 110 including pixels PX, and a gate driver 120 and a data driver 130 that supply driving signals to the pixels PX. The display device 100 may further include additional configurations. For example, the display device 100 may further include a power supply portion for supplying driving voltages to pixels PX, a gate driver 120 and a data driver 130, and a timing control portion for controlling the operations of the gate driver 120 and the data driver 130.

The display panel 110 may include a display area DA and a non-display area NDA. The display area DA is an area where pixels PX are arranged and may be an area where images are displayed by the pixels PX. The non-display area NDA is an area remaining from the display area DA, and images may not be displayed in the non-display area NDA. According to some embodiments, the non-display area NDA may be located around (e.g., in a periphery or outside a footprint of) the display area DA and may surround the display area DA.

In FIGS. 1 and 2, a first direction D1, a second direction D2, and a third direction D3 are defined. According to some embodiments, the first direction D1 may be a horizontal direction of the display panel 110, and the second direction D2 may be a vertical direction of the display panel 110. The third direction D3 may be a thickness direction of the display panel 110.

According to some embodiments, the display panel 110 may be formed in a rectangular shape on a plane. In FIGS. 1 and 2, the display panel 110 is illustrated as having a horizontal length longer than a vertical length, but the shape of the display panel 110 is not limited thereto. For example, the display panel 110 may have a shape in which the vertical length is longer than the transverse length, or may have a square shape, or the like. The display panel 110 may include angled corners or rounded corners. The planar shape of the display panel 110 is not limited to the illustrated rectangular shape, and may have other non-square polygonal, circular, elliptical, irregular, or other shapes.

The display panel 110 may have rigid or flexible characteristics. The display panel 110 may be provided to the display device 100 in an unbent state or may be provided to the display device 100 in a bent state in some sections.

The display panel 110 may include a substrate SUB and pixels PX arranged on the substrate SUB. The pixels PX may be arranged in a display area DA on the substrate SUB.

The substrate SUB may be a base member of the display panel 110. The substrate SUB may include a display area DA and a non-display area NDA surrounding (e.g., in a periphery or outside a footprint of) the display area DA.

The display area DA may have various shapes according to embodiments. For example, the display area DA may have a rectangular shape, a non-rectangular polygonal shape, a circular shape, an oval shape, an irregular shape, or other shapes. According to some embodiments, the display area DA may have a shape that matches the shape of the display panel 110.

The pixels PX may be arranged in the display area DA. For example, the display area DA may include pixel areas in which each pixel PX is arranged.

According to some embodiments, the display device 100 may be a light emitting display device, and the pixel PX may include a light emitting element located in each emission area and a pixel circuit connected to the light emitting element. In describing the embodiments, the term “connection” may include electrical and/or physical connections. Each pixel circuit may include a plurality of pixel transistors and at least one capacitor.

Each pixel PX (or sub-pixel) may emit a specific color of light. The pixels PX of the display area DA may include first pixels emitting light of a first color (e.g., red pixels (or red sub-pixels) emitting red light), second pixels emitting light of a second color (e.g., green pixels (or green sub-pixels) emitting green light), and third pixels emitting light of a third color (e.g., blue pixels (or blue sub-pixels) emitting blue light). At least one first pixel (or first sub-pixel), at least one second pixel (or second sub-pixel), and at least one third pixel (or third sub-pixel) adjacent to each other may form one unit pixel (or pixel) capable of emitting light of various colors including white light.

For example, each pixel PX may be the smallest unit expressing an individual color, and the unit pixel may include a plurality of pixels that emit light of different colors as a group of pixels that are the smallest units that may express standard white (e.g., an achromatic color including white of the highest luminance and gray of a luminance lower than the highest luminance).

The non-display area NDA may include a pad area PA where pads PD are arranged. According to some embodiments, the non-display area NDA may further include a driving circuit area located at least on one side of the display area DA. At least one driving portion, pads PD, and/or wiring may be arranged in the non-display area NDA.

At least one driving portion for driving the pixels PX, or a portion of the driving portion may be arranged in the driving circuit area. According to some embodiments, circuit elements constituting the gate driver 120 (e.g., driving transistors and driving portion capacitors constituting the stages included in the gate driver 120) may be arranged in the driving circuit area on the substrate SUB. The gate driver 120 may be electrically connected to the pixels PX through gate lines.

According to some embodiments, the circuit elements of the gate driver 120 may be formed inside the display panel 110 along with the pixels PX. For example, the driving transistors included in the gate driver 120 may be formed inside the panel circuit layer of the display panel 110 along with the pixel transistors included in the pixels PX. Also, the driving transistors and the pixel transistors may be formed simultaneously using the same material. In this case, the driving transistors may include the material included in the pixel transistors.

The pads PD may be arranged in the pad area PA. At least one circuit board 140 may be arranged and/or bonded on the pads PD. According to some embodiments, a plurality of circuit boards 140 may be arranged on the pads PD. The pads PD may include signal pads and power pads for transmitting driving signals and driving voltages required for driving the pixels PX and the gate driver 120 to the inside of the display panel 110.

The gate driver 120 and the data driver 130 may generate driving signals for controlling the operation timing and brightness of the pixels PX and supply the driving signals to the pixels PX. For example, the gate driver 120 may include a scan driving portion and may be connected to the pixels PX through respective gate lines. The gate driver 120 may supply gate signals (e.g., gate signals that control the driving timing of the pixels PX including scan signals) to the pixels PX. The data driver 130 may be connected to the pixels PX through the data lines. The data driver 130 may supply data signals to the pixels PX.

According to some embodiments, at least one of the gate driver 120 or the data driver 130 may be embedded in the display panel 110. For example, the gate driver 120 may be arranged on the substrate SUB of the display panel 110 and may be arranged and/or formed in the non-display area NDA. According to some embodiments, the gate driver 120 may be arranged in a portion of the non-display area NDA arranged on both sides of the display area DA (e.g., the left and right sides of the display area DA).

According to some embodiments, the data driver 130 may be arranged outside the display panel 110 and electrically connected to the display panel 110. For example, the data driver 130 may be implemented with a plurality of integrated circuit chips and may be arranged on circuit boards 140 electrically connected to pixels PX of the display panel 110. Alternatively, the data driver 130 may be implemented with at least one integrated circuit chip and mounted on a non-display area NDA of the display panel 110.

The circuit board 140 may be connected to the display panel 110 through pads PD. The circuit board 140 may be a flexible film such as a flexible printed circuit board (FPCB), a printed circuit board (PCB), or a chip on film (COF) but is not limited thereto. According to some embodiments, the circuit board 140 may be connected to a timing control portion and/or a power supply portion, etc., through another circuit board or connector.

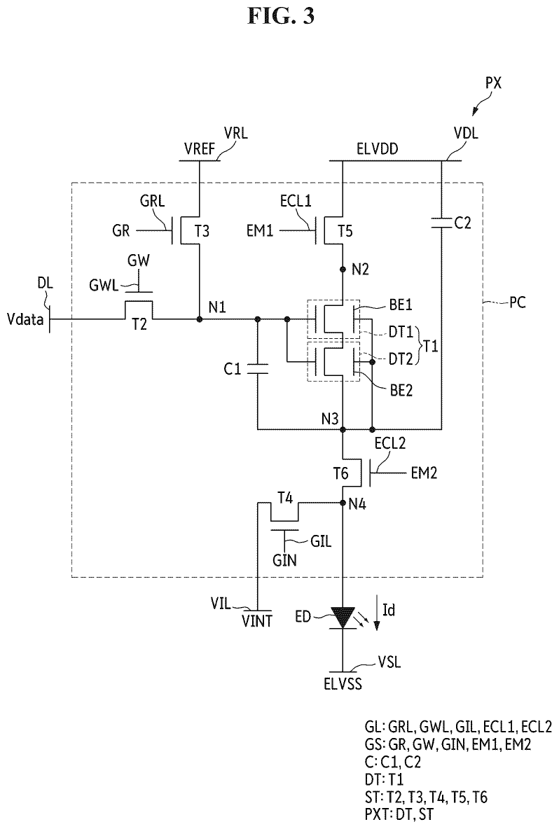

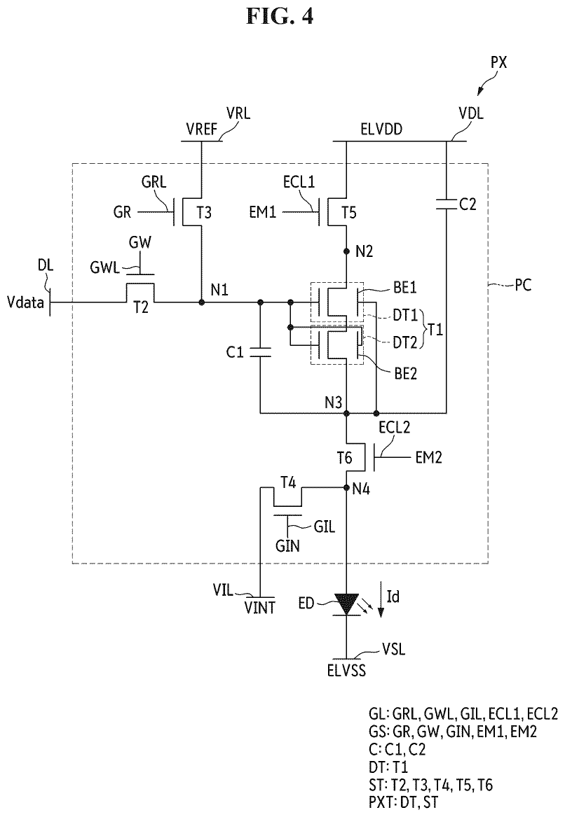

FIG. 3 is a circuit diagram illustrating a pixel according to some embodiments. FIG. 4 is a circuit diagram illustrating a pixel according to some embodiments. Although FIGS. 3 and 4 illustrate various components in a circuit of a pixel according to some embodiments, embodiments according to the present disclosure are not limited thereto, and according to some embodiments the circuit may include additional components or fewer components without departing from the spirit and scope of embodiments according to the present disclosure.

For example, FIGS. 3 and 4 are equivalent circuit diagrams illustrating the configuration of a pixel PX according to some embodiments and illustrate different embodiments with respect to the second driving transistor DT2.

Referring to FIGS. 3 and 4, a pixel PX may include a light emitting element ED and a pixel circuit PC electrically connected to the light emitting element ED. The light emitting element ED is a light source of the pixel PX, and may be, for example, an organic light emitting diode, but is not limited thereto. The pixel circuit PC may control light emission of the light emitting element ED.

The pixel circuit PC may supply a driving current Id to the light emitting element ED in response to driving signals supplied from the gate driver 120 and the data driver 130. For example, the pixel circuit PC may supply the driving current Id to the light emitting element ED in response to each of the gate signals GS supplied from the gate driver 120 through each of the gate lines GL and the data signal Vdata supplied from the data driver 130 through the data line DL.

According to some embodiments, the pixel PX may be electrically connected to a first gate line GWL for transmitting a first gate signal GW (e.g., a scan signal), a second gate line GIL for transmitting a second gate signal GIN, a third gate line GRL for transmitting a third gate signal GR, a first light emitting control line ECL1 for transmitting a first light emitting control signal EM1, a second light emitting control line ECL2 for transmitting a second light emitting control signal EM2, and a data line DL for transmitting a data signal Vdata. Also, the pixel PX may be further connected to a first power supply line VDL for transmitting a first driving voltage ELVDD (e.g., a first pixel voltage having a high potential), a second power supply line VSL for transmitting a second driving voltage ELVSS (e.g., a second pixel voltage having a low potential), an initialization power supply line VIL for transmitting an initialization voltage VINT, and a reference power supply line VRL for transmitting a reference voltage VREF. The types and numbers of signal lines and power supply lines connected to the pixel PX may vary depending on the structure or operation method of the pixel PX.

The pixel circuit PC may include pixel transistors PXT and at least one capacitor C. The pixel transistors PXT may include a driving transistor DT and at least one switching transistor ST.

According to some embodiments, the pixel circuit PC may include a first transistor T1 as a driving transistor DT of the pixel PX, and a second transistor T2, a third transistor T3, a fourth transistor T4, a fifth transistor T5, and a sixth transistor T6 as switching transistors ST of the pixel PX. According to some embodiments, the pixel circuit PC may include a plurality of capacitors C. For example, the pixel circuit PC may include a first capacitor C1 and a second capacitor C2. However, the structure of the pixel circuit PC is not limited to the embodiments of FIG. 3 or FIG. 4, and the structure, input signal, and/or operation method of the pixel circuit PC may be variously changed according to the embodiments.

The first transistor T1 may control the size of the driving current Id supplied to the light emitting element ED according to the gate-source voltage. The switching transistors ST may be turned on or off according to the respective gate-source voltages. Depending on the type (e.g., a P-type or N-type transistor) and/or the operating condition of each of the pixel transistors PXT, the first electrode of each of the pixel transistors PXT may be a drain electrode (or a drain region) or a source electrode (or a source region), and the second electrode may be an electrode different from the first electrode. For example, when the first electrode is a drain electrode, the second electrode may be a source electrode.

According to some embodiments, the pixel transistors PXT may be N-type transistors. Further, the pixel transistors PXT may be oxide transistors including oxide semiconductors. For example, the active layer of each of the pixel transistors PXT may be formed of an oxide semiconductor. The pixel transistors PXT including the oxide semiconductor may have uniform operating characteristics and may have small leakage current.

According to some embodiments, the transistors formed in the display panel 110, including the pixel transistors PXT included in each pixel PX, may all be oxide transistors including oxide semiconductors. The oxide semiconductor has high carrier mobility and low leakage current, and thus, even if the driving time of the oxide transistor is long, a large voltage drop may not occur. Furthermore, the characteristic dispersion of the pixel transistors PXT may be small, and thus, the operating characteristics of the pixels PX may be uniform. Accordingly, the image quality and reliability of the display device 100 may be relatively improved, and power consumption may be reduced.

According to some embodiments, the first transistor T1 may be a dual-structured driving transistor DT including a first driving transistor DT1 and a second driving transistor DT2. The first driving transistor DT1 and the second driving transistor DT2 may be connected in series between a second node N2 and a third node N3, and a gate electrode of the first driving transistor DT1 and a gate electrode of the second driving transistor DT2 may be commonly connected to the first node N1. The first transistor T1 may control a driving current Id flowing to the light emitting element ED according to a voltage of the first node N1 (e.g., a voltage corresponding to a data signal Vdata).

The first driving transistor DT1 may include a first electrode (e.g., a drain electrode or a drain region) electrically connected to a second node N2, and a second electrode (e.g., a source electrode or a source region) electrically connected to the first electrode of the second driving transistor DT2. The second driving transistor DT2 may include a first electrode (e.g., a drain electrode or a drain region) electrically connected to the second electrode of the first driving transistor DT1, and a second electrode (e.g., a source electrode or a source region) electrically connected to a third node N3. The gate electrodes of the first driving transistor DT1 and the second driving transistor DT2 may be electrically connected to the first node N1.

According to some embodiments, the first driving transistor DT1 and the second driving transistor DT2 may include a first bottom electrode BE1 and a second bottom electrode BE2 opposite the respective gate electrodes across the respective channel regions. According to some embodiments, the first driving transistor DT1 may include a first bottom electrode BE1 arranged below a channel region of the first driving transistor DT1, and the second driving transistor DT2 may include a second bottom electrode BE2 arranged below a channel region of the second driving transistor DT2. The operating characteristics of the first transistor T1 may be adjusted or relatively improved by utilizing the first bottom electrode BE1 and the second bottom electrode BE2.

According to some embodiments, as shown in FIG. 3, the first bottom electrode BE1 and the second bottom electrode BE2 may be commonly connected to a source electrode or a source region of the first transistor T1. For example, by electrically connecting the first bottom electrode BE1 and the second bottom electrode BE2 to the third node N3, the subthreshold slope SS of the first transistor T1 may be increased. Accordingly, even when the pixel PX is made to emit light at a low luminance by a fine driving current Id, the driving current Id of the pixel PX may be controlled more precisely, and the low-grayscale expressiveness of the display device 100 may be relatively improved.

According to some embodiments, as shown in FIG. 4, the first bottom electrode BE1 may be electrically connected to the third node N3, and the second bottom electrode BE2 may be electrically connected to the first node N1. Accordingly, the subthreshold slope of the first transistor T1 may be secured, and at the same time, the on-current of the first transistor T1 may be increased, thereby reducing the data voltage swing range DSR. Accordingly, the image quality and power consumption of the display device 100 may be relatively improved.

The second transistor T2 may include a gate electrode electrically connected to the first gate line GWL, a first electrode electrically connected to the data line DL, and a second electrode electrically connected to the first node N1. The second transistor T2 may be turned on by a first gate signal GW transmitted to the first gate line GWL (e.g., a first gate signal GW of a gate-on voltage corresponding to a high-level) to electrically connect the data line DL and the first node N1. When the second transistor T2 is turned on, a data signal Vdata transmitted to the data line DL may be transmitted to the first node N1.

The third transistor T3 may include a gate electrode electrically connected to the third gate line GRL, a first electrode electrically connected to the reference power line VRL, and a second electrode electrically connected to the first node N1. The third transistor T3 may be turned on by the third gate signal GR transmitted to the third gate line GRL and may transmit the reference voltage VREF transmitted to the reference power line VRL to the first node N1.

The fourth transistor T4 may include a gate electrode electrically connected to the second gate line GIL, a first electrode electrically connected to the fourth node N4, and a second electrode electrically connected to the initialization power supply line VIL. The fourth transistor T4 may be turned on by the second gate signal GIN transmitted to the second gate line GIL and may transmit the initialization voltage VINT transmitted to the initialization power supply line VIL to the fourth node N4.

The fifth transistor T5 may include a gate electrode electrically connected to the first light emitting control line ECL1, a first electrode electrically connected to the first power supply line VDL, and a second electrode electrically connected to the second node N2. The fifth transistor T5 may be turned on by the first light emitting control signal EM1 transmitted to the first light emitting control line ECL1 and may electrically connect the first power supply line VDL and the first transistor T1.

The sixth transistor T6 may include a gate electrode electrically connected to the second light emitting control line ECL2, a first electrode electrically connected to the third node N3, and a second electrode electrically connected to the fourth node N4. The sixth transistor T6 may be turned on by the second light emitting control signal EM2 transmitted to the second light emitting control line ECL2 and may electrically connect the first transistor T1 and the light emitting element ED.

According to some embodiments, by individually supplying the first light emitting control signal EM1 and the second light emitting control signal EM2 to the gate electrode of the fifth transistor T5 and the gate electrode of the sixth transistor T6, respectively, the driving of the fifth transistor T5 and the sixth transistor T6 may be independently controlled. For example, even if the fifth transistor T5 is turned on by the first light emitting control signal EM1 of the gate-on voltage during the non-emission period of the pixel PX, the sixth transistor T6 may be turned off by the second light emitting control signal EM2 of the gate-off voltage, thereby preventing or reducing voltage fluctuations of the third node N3 due to the second driving voltage ELVSS, etc. During the emission period of the pixel PX, both the fifth transistor T5 and the sixth transistor T6 may be turned on by the first light emitting control signal EM1 and the second light emitting control signal EM2 of the gate-on voltage. Accordingly, a driving current Id may flow to the pixel PX.

The first capacitor C1 may be electrically connected between the first node N1 and the third node N3. The first capacitor C1 may be a storage capacitor of the pixel PX and may store a voltage corresponding to a data signal Vdata.

The second capacitor C2 may be electrically connected between the first power supply line VDL and the third node N3. The second capacitor C2 may be a hold capacitor of the pixel PX and may play a role in stabilizing the operating characteristics of the pixel PX.

The light emitting element ED may be electrically connected between the fourth node N4 and the second power supply line VSL. For example, the light emitting element ED may include a first electrode (e.g., an anode electrode) electrically connected to a fourth node N4, a second electrode (e.g., a cathode electrode) facing the first electrode and connected to the second power supply line VSL, and a light emitting layer interposed between the first electrode and the second electrode. According to some embodiments, the first electrode of the light emitting element ED may be a pixel electrode individually arranged in each pixel PX, and the second electrode of the light emitting element ED may be a common electrode shared by a plurality of pixels PX. The light emitting element ED may emit light with a luminance corresponding to the driving current Id during a period in which the driving current Id flows through the pixel PX. The light emitting element ED may emit light of a specific color (e.g., red light, green light, blue light, or white light).

According to embodiments, by forming the first transistor T1 operating as the driving transistor DT of the pixel PX as a dual-structure transistor including the first driving transistor DT1 and the second driving transistor DT2, the channel length of the first transistor T1 may be increased. Accordingly, the subthreshold slope of the light emitting element ED may be stably secured.

In addition, according to embodiments, the characteristics of the first transistor T1 may be adjusted or optimized by utilizing the first bottom electrode BE1 of the first driving transistor DT1 and the second bottom electrode BE2 of the second driving transistor DT2. For example, the first bottom electrode BE1 and the second bottom electrode BE2 may be connected to the third node N3 to increase the subthreshold slope of the first transistor T1. Alternatively, the first bottom electrode BE1 and the second bottom electrode BE2 may be connected to the third node N3 and the first node N1, respectively, to increase the subthreshold slope and the on-current of the first transistor T1.

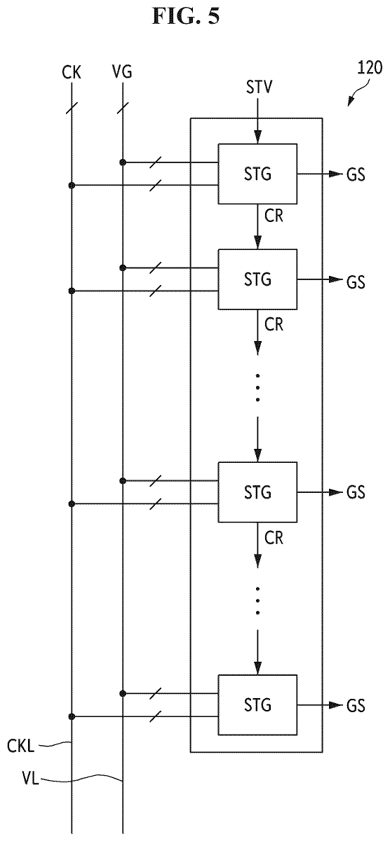

FIG. 5 is a diagram schematically illustrating a gate driver according to some embodiments. FIG. 5 schematically illustrates one gate signal generation portion that sequentially outputs one type of gate signal GS (e.g., the first gate signal GW in FIG. 3) as a configuration that may be included in the gate driver 120. According to some embodiments, when each pixel PX is driven by a plurality of gate signals GS, the gate driver 120 may include a plurality of gate signal generation portions for outputting the plurality of gate signals GS.

Referring to FIG. 5 in addition to FIGS. 1 to 4, the gate driver 120 may include a plurality of stages STG that sequentially output the gate signals GS. Each stage STG may receive at least one clock signal CK and at least one driving voltage VG from at least one clock line CKL and at least one voltage line VL, respectively. For example, the stage STG may receive a plurality of clock signals CK (e.g., a plurality of clock signals CK having different waveforms and/or phases) and a plurality of driving voltages VG (e.g., a plurality of driving voltages VG including a gate-high voltage and a gate-low voltage) from a plurality of clock lines CKL and a plurality of voltage lines VL, respectively and may output a gate signal GS in response. The stage STG may further output a carry signal CR to the previous stage STG and/or the previous stage STG.

According to some embodiments, some of the stages STG included in the gate driver 120 and other some of the stages STG may be driven by different clock signals CK. For example, at least one clock signal CK including a first clock signal may be input to some stages STG, and at least one other clock signal CK including a second clock signal different from the first clock signal may be input to other stages STG.

According to some embodiments, the plurality of stages STG may sequentially output gate signals GS in response to a scan start signal, for example, a start pulse STV, input from the outside. For example, the first stage STG may receive the start pulse STV through a signal line electrically connected to a timing control portion and may output the gate signal GS and a carry signal CR using the start pulse STV. Other stages STG may output their respective gate signals GS and carry signals CR using the carry signal CR input from the stage STG of the previous stage.

The types, structures, and/or numbers of gate signal generating units include the gate driver 120 may be varied in various ways depending on the embodiments. Also, the structures and operation methods of the stages STG included in each gate signal generating portion, the types, waveforms, and/or numbers of the input/output signals of the stages STG, etc. may be varied in various ways depending on the embodiments.

According to some embodiments, the gate driver 120 may be formed inside the display panel 110 along with the pixels PX. For example, each of the stages STG may include driving transistors formed inside the display panel 110 along with the pixel transistors PXT of FIG. 3 or FIG. 4.

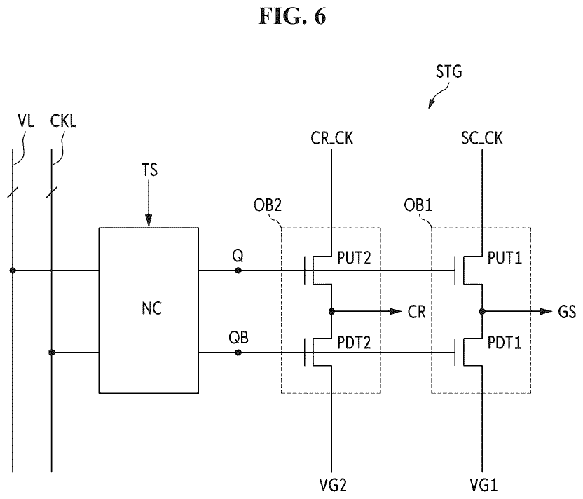

FIG. 6 is a diagram schematically illustrating a stage of a gate driver according to some embodiments. For example, FIG. 6 schematically illustrates an arbitrary stage STG included in the gate driver 120 according to some embodiments.

Referring to FIG. 6, the stage STG may include a control circuit NC for controlling voltage levels of a first control node Q and a second control node QB, a first output circuit OB1 for outputting a gate signal GS, and a second output circuit OB2 for outputting a carry signal CR.

The control circuit NC may be arranged at an input terminal of the stage STG and may receive an input signal TS including a start pulse STV or a carry signal CR. The control circuit NC may control the voltage levels of the first control node Q and the second control node QB in response to the input signal TS. The control circuit NC may include control transistors for controlling the voltage levels of the first control node Q and the second control node QB in response to the input signal TS. For example, the control circuit NC may be configured as a logic circuit including a plurality of control transistors.

The first output circuit OB1 may include a first pull-up transistor PUT1 and a first pull-down transistor PDT1 electrically connected between a terminal to which a scan clock signal SC_CK is input and a terminal to which a first voltage VG1 (e.g., a first gate-low voltage of a first level) is input. The second output circuit OB2 may include a second pull-up transistor PUT2 and a second pull-down transistor PDT2 electrically connected between a terminal to which a carry clock signal CR_CK is input and a terminal to which a second voltage VG2 (e.g., a second gate-low voltage of a second level) is input. The first and second pull-up transistors PUT1 and PUT2 and the first and second pull-down transistors PDT1 and PDT2 may be buffer transistors that serve as output buffers that strengthen a signal generated in the stage STG.

The gate electrodes of each of the first and second pull-up transistors PUT1 and PUT2 may be electrically connected to the first control node Q. The first and second pull-up transistors PUT1 and PUT2 may be turned on or turned off depending on the voltage level of the first control node Q. For example, the first and second pull-up transistors PUT1 and PUT2 may be turned on during a period in which a high-level voltage is applied to the first control node Q.

The gate electrodes of each of the first and second pull-down transistors PDT1 and PDT2 may be electrically connected to the second control node QB. The first and second pull-down transistors PDT1 and PDT2 may be turned on or turned off depending on the voltage level of the second control node QB. For example, the first and second pull-down transistors PDT1 and PDT2 may be turned on during a period in which a high-level voltage is applied to the second control node QB.

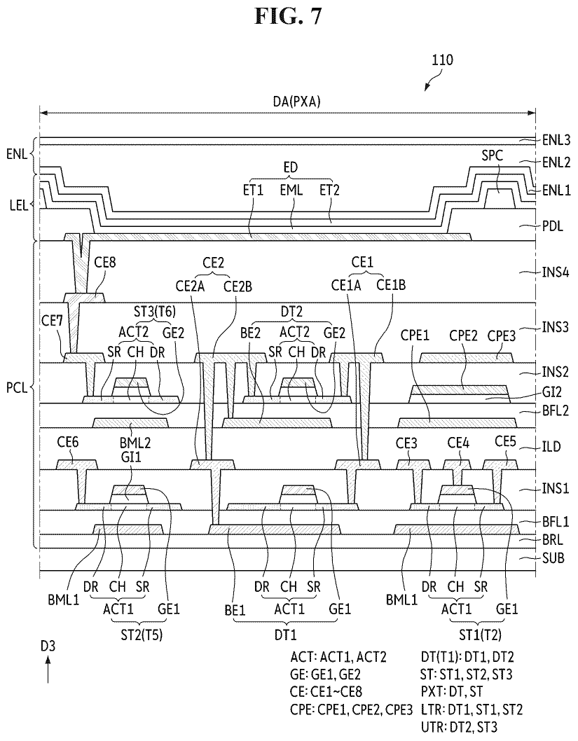

FIG. 7 is a cross-sectional view illustrating a portion of a display panel according to some embodiments. For example, FIG. 7 illustrates a portion of a pixel area PXA included in the display area DA of the display panel 110. The pixel area PXA may be an area where circuit elements of a pixel PX (e.g., pixel transistors PXT and capacitors C in FIG. 3 or FIG. 4) and a light emitting element ED are arranged.

Referring to FIG. 7 in addition to FIGS. 1 to 6, the display panel 110 may include a substrate SUB, a panel circuit layer PCL, a light emitting element layer LEL, and an encapsulation layer ENL sequentially arranged on the substrate SUB.

According to some embodiments, the display panel 110 may further include additional elements arranged on top and/or bottom of the encapsulation layer ENL. For example, the display panel 110 may further include at least one of a sensor layer (e.g., a touch sensor layer), an optical layer (e.g., a color filter layer and/or a wavelength conversion layer), or a protective layer (e.g., a protective film, an insulating layer, an upper substrate, and/or a window).

The substrate SUB is a base member for forming the display panel 110 and may be a rigid or flexible substrate (or film). According to some embodiments, the substrate SUB may be a substrate that includes an insulating material such as glass and has rigid characteristics and may not be bent. Alternatively, the substrate SUB may be a flexible substrate that includes polyimide or another insulating material and is capable of being bent, folded, rolled, or the like and may be bent or not bent.

The substrate SUB may include a display area including pixel areas PXA in which each pixel PX is arranged. The substrate SUB may further include a non-display area NDA including a driving circuit area where a gate driver 120 is arranged and a pad area PA where pads PD are arranged.

A panel circuit layer PCL (e.g., a thin film transistor layer or a backplane layer) may be arranged on the substrate SUB. The panel circuit layer PCL may include circuit elements including pixel transistors PXT and capacitors C included in pixels PX, and signal lines and power supply lines connected to the pixels PX. The substrate SUB and the panel circuit layer PCL may form a backplane substrate of the display panel 110.

FIG. 7 illustrates a driving transistor DT and a first switching transistor ST1, a second switching transistor ST2, and a third switching transistor ST3 that may be included in a single pixel PX, as an example of circuit elements that may be included in the panel circuit layer PCL. According to some embodiments, the driving transistor DT of FIG. 7 may be the first transistor T1 of FIG. 3 and may include a first driving transistor DT1 and a second driving transistor DT2. According to some embodiments, the first switching transistor ST1, the second switching transistor ST2, and the third switching transistor ST3 of FIG. 7 may be the second transistor T2, the fifth transistor T5, and the sixth transistor T6 of FIG. 3, respectively.

Each of the pixel transistors PXT may include an active layer ACT, and a gate electrode GE overlapping a portion of the active layer ACT. For example, each of the first driving transistor DT1, the second driving transistor DT2, the first switching transistor ST1, the second switching transistor ST2, and the third switching transistor ST3 may include an active layer ACT, and a gate electrode GE arranged on a portion of the active layer ACT.

The panel circuit layer PCL according to some embodiments may include lower transistors LTR arranged in a lower layer and upper transistors UTR arranged in an upper layer. At least some of the lower transistors LTR and at least some of the upper transistors UTR may overlap each other in a thickness direction of a substrate SUB (e.g., a third direction D3). For example, the panel circuit layer PCL may include pixel transistors PXT stacked in a two-layer structure in each pixel area PXA.

The active layer ACT of each of the lower transistors LTR may also be referred to as a “first active layer ACT1”, and the gate electrode GE of each of the lower transistors LTR may also be referred to as a “first gate electrode GE1”. The active layer ACT of each of the upper transistors UTR may also be referred to as a “second active layer ACT2”, and the gate electrode GE of each of the upper transistors UTR may also be referred to as a “second gate electrode GE2”.

The first driving transistor DT1 and the second driving transistor DT2 may be arranged in different layers. For example, the first driving transistor DT1 may be formed as a lower transistor LTR arranged in a lower layer of the panel circuit layer PCL, and the second driving transistor DT2 may be formed as an upper transistor UTR arranged in an upper layer of the panel circuit layer PCL.

According to some embodiments, the first driving transistor DT1 and the second driving transistor DT2 may overlap each other. For example, the first driving transistor DT1 and the second driving transistor DT2 may overlap each other in the third direction D3, and the second driving transistor DT2 may be arranged on at least a portion of the first driving transistor DT1.

Some of the switching transistors ST of the pixel PX may be formed as lower transistors LTR along with the first driving transistor DT1. For example, the first switching transistor ST1 and the second switching transistor ST2 are located in the lower layer of the panel circuit layer PCL and may be formed simultaneously with the first driving transistor DT1. Other portions of the switching transistors ST of the pixel PX may be formed as upper transistors UTR along with the second driving transistor DT2. In one example, a third switching transistor ST3 may be arranged on an upper layer of the panel circuit layer PCL and may be formed simultaneously with the second driving transistor DT2.

However, the embodiments according to the present disclosure are not limited thereto. For example, the switching transistors ST of the pixel PX may be formed with only the lower transistors LTR or may be formed with only the upper transistors UTR.

According to some embodiments, a bottom electrode or a bottom conductive pattern (or a light blocking pattern) may be arranged below the active layer ACT of each of the pixel transistors PXT. Accordingly, external light may be blocked from entering the channel region CH and the like from the lower portion of each of the active layers ACT, and the operating characteristics of each of the pixel transistors PXT may be stabilized. However, the embodiments according to the present disclosure are not limited thereto. For example, only some of the pixel transistors PXT may have a respective bottom electrode or bottom conductive pattern arranged below them.

The pixel PX may further include a plurality of capacitor electrodes CPE that overlap each other. The capacitor C of the pixel PX (e.g., the first capacitor C1 and the second capacitor C2 in FIG. 3 or FIG. 4) may be formed by utilizing the electrostatic capacitance formed at the portion where the capacitor electrodes CPE overlap. According to some embodiments, the capacitor electrodes CPE may be arranged on an upper layer of the panel circuit layer PCL with the upper transistors UTR or may be arranged on a lower layer of the panel circuit layer PCL with the lower transistors LTR. According to some embodiments, some of the capacitor electrodes CPE may be arranged on an upper layer of the panel circuit layer PCL, and other some of the capacitor electrodes CPE may be arranged on a lower layer of the panel circuit layer PCL. For example, the capacitor electrodes CPE may be formed of conductive patterns included in at least some of the conductive layers of the panel circuit layer PCL. FIG. 7 illustrates embodiments in which the capacitor electrodes CPE are arranged on an upper layer of the panel circuit layer PCL with the upper transistors UTR.

The panel circuit layer PCL may further include a plurality of insulating layers arranged around the circuit elements and wirings. For example, the panel circuit layer PCL may include a barrier layer BRL, a first buffer layer BFL1, a first gate insulating layer GI1, a first insulating layer INS1, an interlayer insulating layer ILD, a second buffer layer BFL2, a second gate insulating layer GI2, a second insulating layer INS2, a third insulating layer INS3, and a fourth insulating layer INS4 sequentially arranged on the substrate SUB.

The barrier layer BRL may include a material suitable for protecting the pixels PX from moisture penetrating through the substrate SUB that is vulnerable to moisture permeation. For example, the barrier layer BRL may include at least one inorganic insulating layer including an inorganic insulating material (e.g., silicon nitride, silicon oxide, silicon oxynitride, titanium oxide, aluminum oxide, or another inorganic insulating material).

A first conductive layer (e.g., a first bottom metal layer) including a first bottom electrode BE1 of the first driving transistor DT1 may be arranged on the barrier layer BRL. According to some embodiments, the first conductive layer may further include first bottom conductive patterns BML1 overlapping with switching transistors ST formed by lower transistors LTR. For example, the first conductive layer may further include first bottom conductive patterns BML1 overlapping with first active layers ACT1 of the first and second switching transistors ST1 and ST2.

The first bottom electrode BE1 may be formed below the first active layer ACT1 included in the first driving transistor DT1 and may overlap the channel region CH of the first driving transistor DT1. The first bottom conductive patterns BML1 may be located below each of the first active layers ACT1 of the first and second switching transistors ST1 and ST2 and may overlap with the channel regions CH of each of the first and second switching transistors ST1 and ST2. For example, the first bottom electrode BE1 and the first bottom conductive pattern BML1 are arranged below the first active layer ACT1 of the lower transistors LTR and may be formed simultaneously using the same material.

The patterns of the first conductive layer, including the first bottom electrode BE1 and the first bottom conductive patterns BML1, may include at least one conductive material. For example, the patterns of the first conductive layer may include at least one of copper (Cu), titanium (Ti), molybdenum (Mo), aluminum (Al), chromium (Cr), gold (Au), silver (Ag), platinum (Pt), palladium (Pd), nickel (Ni), neodymium (Nd), iridium (Ir), tantalum (Ta), tungsten (W), magnesium (Mg), or other metals, alloys thereof, or other conductive materials. Each of the patterns of the first conductive layer may be formed of a single layer or multiple layers of electrodes, conductive patterns, or wiring.

A first buffer layer BFL1 may be arranged on the first conductive layer. For example, the first buffer layer BFL1 may be arranged on the barrier layer BRL to cover the patterns on the first conductive layer.

The first buffer layer BFL1 may be formed of a single layer or multiple layers of insulating layers including at least one insulating material. For example, the first buffer layer BFL1 may include at least one inorganic insulating layer including an inorganic insulating material (e.g., silicon nitride, silicon oxide, silicon oxynitride, titanium oxide, aluminum oxide, or other inorganic insulating material).

A first semiconductor layer (e.g., a lower semiconductor layer) including first active layers ACT1 of lower transistors LTR may be arranged on the first buffer layer BFL1. For example, the first semiconductor layer may include first active layers ACT1 of each of the first driving transistor DT1, the first switching transistor ST1, and the second switching transistors ST.

Each of the first active layer ACT1 may include a channel region CH overlapping the respective first gate electrode GE1, and a source region SR and a drain region DR arranged on different sides of the channel region CH. The source region SR and the drain region DR may have a higher carrier concentration (e.g., electron concentration) compared to the channel region CH.

According to some embodiments, the patterns of the first semiconductor layer including the first active layers ACT1 may include an oxide semiconductor. For example, the patterns of the first semiconductor layer may include a metal oxide including at least one of indium (In), gallium (Ga), zinc (Zn), tin (Sn), hafnium (Hf), zirconium (Zr), or aluminum (Al). For example, each of the first active layers (ACT1) may include at least one of zinc oxide (ZnO), zinc-tin oxide (ZTO), indium-zinc oxide (IZO), indium oxide (InO or In₂O₃), titanium oxide (TiO or TiO₂), indium-gallium oxide (IGO), indium-gallium-zinc oxide (IGZO), indium-gallium-tin oxide (IGTO), indium-zinc-tin oxide (IZTO), indium-tin-gallium-zinc oxide (ITGZO), or another oxide semiconductor. The first active layers ACT1 may be formed simultaneously using the same material.

A first gate insulating layer GI1 may be arranged on the first semiconductor layer. According to some embodiments, the first gate insulating layer GI1 may have an etched shape to cover only a portion of each of the first active layers ACT1 including the channel region CH, and not cover other portions (e.g., the source region SR and the drain region DR) of each of the first active layers ACT1. According to some embodiments, the first gate insulating layer GI1 may be arranged entirely on the first buffer layer BFL1 and the first active layers ACT1.

The first gate insulating layer GI1 may be formed of a single layer or multiple layers of insulating layers including at least one insulating material. For example, the first gate insulating layer GI1 may include at least one inorganic insulating layer including an inorganic insulating material (e.g., silicon oxide, silicon nitride, silicon oxynitride, titanium oxide, aluminum oxide, or other inorganic insulating material).

A second conductive layer (e.g., a first gate metal layer) including first gate electrodes GE1 of lower transistors LTR may be arranged on the first gate insulating layer GI1. For example, the second conductive layer may include the first gate electrodes GE1 of each of the first driving transistor DT1, the first switching transistor ST1, and the second switching transistor ST2.

The first gate electrode GE1 of the first driving transistor DT1 may be arranged on a portion of the first gate insulating layer GI1 covering the channel region CH of the first driving transistor DT1. The first gate electrode GE1 of the first switching transistor ST1 may be arranged on a portion of the first gate insulating layer GI1 covering the channel region CH of the first switching transistor ST1. The first gate electrode GE1 of the second switching transistor ST2 may be arranged on a portion of the first gate insulating layer GI1 covering the channel region CH of the second switching transistor ST2.

The patterns of the second conductive layer including the first gate electrodes GE1 may include at least one conductive material. For example, the patterns of the second conductive layer may include at least one of the conductive materials of the material of the first conductive layer, or other conductive materials. Each of the patterns of the second conductive layer may be formed of a single layer or multiple layers of electrodes, conductive patterns, or wiring.

A first insulating layer INS1 may be arranged on the second conductive layer. The first insulating layer INS1 may entirely cover the lower transistors LTR and the first gate insulating layer GI1.

The first insulating layer INS1 may be formed of a single layer or multiple layers of insulating layers including at least one insulating material. For example, the first insulating layer INS1 may include at least one inorganic insulating layer including an inorganic insulating material (e.g., at least one of the inorganic insulating materials of the material of the first buffer layer BFL1, or another inorganic insulating material).

A third conductive layer (e.g., a first source-drain metal layer) including connection electrodes CE electrically connected to the lower transistors LTR may be arranged on the first insulating layer INS1. For example, the third conductive layer may include lower electrodes CE1A and CE2A of the first and second connection electrodes CE1 and CE2, and third, fourth, fifth, and sixth connection electrodes CE3, CE4, CE5, and CE6.

A lower electrode CE1A of the first connection electrode CE1 may be electrically connected between the first driving transistor DT1 and the second driving transistor DT2. For example, the lower electrode CE1A of the first connection electrode CE1 may be electrically connected to the source region SR of the first driving transistor DT1 through a contact hole through the first insulating layer INS1. Further, the lower electrode CE1A of the first connection electrode CE1 may be electrically connected to the drain region DR of the second driving transistor DT2 via the upper electrode CE1B of the first connection electrode CE1.

The lower electrode CE2A of the second connection electrode CE2 may be electrically connected between the first bottom electrode BE1 of the first driving transistor DT1 and the source region SR of the second driving transistor DT2. For example, the lower electrode CE2A of the second connecting electrode CE2 may be electrically connected to the first bottom electrode BE1 through a contact hole penetrating the first insulating layer INS1 and the first buffer layer BFL1. Further, the lower electrode CE2A of the second connection electrode CE2 may be electrically connected to the source region SR of the second driving transistor DT2 via the upper electrode CE2B of the second connection electrode CE2.

According to some embodiments, the third conductive layer may further include a first gate connection electrode electrically connected to the first gate electrode GE1 of the first driving transistor DT1. When the first driving transistor DT1 is the first driving transistor DT1 of FIG. 3 or 4, the first gate connection electrode may be electrically connected to the first node N1.

The third connection electrode CE3 may be electrically connected to the drain region DR of the first switching transistor ST1. When the first switching transistor ST1 is the second transistor T2 of FIG. 3 or 4, the third connection electrode CE3 may be electrically connected to the data line DL.

The fourth connection electrode CE4 may be electrically connected to the first gate electrode GE1 of the first switching transistor ST1. When the first switching transistor ST1 is the second transistor T2 of FIG. 3 or 4, the fourth connection electrode CE4 may be electrically connected to the first gate line GWL.

The fifth connection electrode CE5 may be electrically connected to the source region SR of the first switching transistor ST1. When the first switching transistor ST1 is the second transistor T2 of FIG. 3 or FIG. 4, the fifth connection electrode CE5 may be electrically connected to the first node N1.

The sixth connection electrode CE6 may be electrically connected to the drain region DR of the second switching transistor ST2. When the second switching transistor ST2 is the fifth transistor T5 of FIG. 3 or FIG. 4, the sixth connecting electrode CE6 may be electrically connected to the first power supply line VDL.

According to some embodiments, the source region SR of the second switching transistor ST2 may be formed integrally with the first active layer ACT1 of another circuit element. In one example, the source region SR of the second switching transistor ST2 and the drain region DR of the first drive transistor DT1 may be integrally formed. For example, in FIG. 7, the source region SR of the second switching transistor ST2 and the drain region DR of the first driving transistor DT1 are illustrated separated from each other, but the source region SR of the second switching transistor ST2 and the drain region DR of the first driving transistor DT1 may be connected to each other when viewed in a plan view.

According to some embodiments, the third conductive layer may further include a second gate connection electrode electrically connected to the first gate electrode GE1 of the second switching transistor ST2. When the second switching transistor ST2 is the fifth transistor T5 of FIG. 3 or 4, the second gate connection electrode may be electrically connected to the first light emitting control line ECL1.

The patterns of the third conductive layer, including the connection electrodes CE on the first insulating layer INS1, may include at least one conductive material. For example, the patterns of the third conductive layer may include at least one of the conductive materials of the material of the first conductive layer, or other conductive materials. Each of the patterns of the third conductive layer may be formed of a single layer or multiple layers of electrodes, conductive patterns, or wiring.

An interlayer insulating layer ILD may be arranged on the third conductive layer. The interlayer insulating layer ILD may entirely cover the first insulating layer INS1 and the patterns of the third conductive layer. The interlayer insulating layer ILD may be arranged between a lower layer of a panel circuit layer PCL including lower transistors LTR and an upper layer of a panel circuit layer PCL including upper transistors UTR. The lower layer of the panel circuit layer PCL may include the first conductive layer, the first semiconductor layer, the second conductive layer, and the third conductive layer sequentially arranged on the barrier layer BRL.

The interlayer insulating layer ILD may be formed of a single layer or multiple layers of insulating layers including at least one insulating material. For example, the interlayer insulating layer ILD may include at least one inorganic insulating layer including an inorganic insulating material (e.g., at least one of the inorganic insulating materials of the material of the first buffer layer BFL1, or another inorganic insulating material).

A fourth conductive layer (e.g., a second bottom metal layer) including a second bottom electrode BE2 of the second driving transistor DT2 may be arranged on the interlayer insulation layer ILD. According to some embodiments, the fourth conductive layer may further include a second bottom conductive pattern BML2 overlapping with a switching transistor ST formed by an upper transistor UTR. For example, the fourth conductive layer may further include the second bottom conductive pattern BML2 overlapping with the second active layer ACT2 of the third switching transistor ST3. According to some embodiments, the fourth conductive layer may further include a first capacitor electrode CPE1.

The second bottom electrode BE2 may be arranged below the second active layer ACT2 included in the second driving transistor DT2 and may overlap with the channel region CH of the second driving transistor DT2. The second bottom conductive pattern BML2 may be arranged below the second active layer ACT2 of the third switching transistor ST3 and may overlap with the channel region CH of the third switching transistor ST3. For example, the second bottom electrode BE2 and the second bottom conductive pattern BML2 may be located below the second active layer ACT2 of the upper transistors UTR.

The first capacitor electrode CPE1 may overlap at least one other capacitor electrode CPE. At least one capacitor C may be formed by utilizing the first capacitor electrode CPE1. The second bottom electrode BE2, the second bottom conductive pattern BML2, and the first capacitor electrode CPE1 may be formed simultaneously using the same material.

The patterns of the fourth conductive layer including the second bottom electrode BE2, the second bottom conductive pattern BML2, and/or the first capacitor electrode CPE1 may include at least one conductive material. For example, the patterns of the fourth conductive layer may include at least one of the conductive materials of the material of the first conductive layer, or other conductive materials. Each of the patterns of the fourth conductive layer may be formed of a single layer or multiple layers of electrodes, conductive patterns, or wiring.

A second buffer layer BFL2 may be arranged on the fourth conductive layer. For example, the second buffer layer BFL2 may be arranged on an interlayer insulating layer ILD to cover the patterns of the fourth conductive layer.

The second buffer layer BFL2 may be formed of a single layer or multiple layers of insulating layers including at least one insulating material. For example, the second buffer layer BFL2 may include at least one inorganic insulating layer including an inorganic insulating material (e.g., at least one of the inorganic insulating materials of the material in the first buffer layer BFL1, or another inorganic insulating material).

A second semiconductor layer (e.g., an upper semiconductor layer) including the second active layer ACT2 of the upper transistors UTR may be arranged on the second buffer layer BFL2. For example, the second semiconductor layer may include the second active layer ACT2 of each of the second driving transistor DT2 and the third switching transistor ST3.

Each of the second active layers ACT2 may include a channel region CH overlapping with each of the second gate electrodes GE2, and a source region SR and a drain region DR arranged on different sides of the channel region CH. The source region SR and the drain region DR may have a higher carrier concentration compared to the channel region CH.

According to some embodiments, the patterns of the second semiconductor layer including the second active layers ACT2 may include an oxide semiconductor. For example, the patterns of the second semiconductor layer may include a metal oxide including at least one of indium (In), gallium (Ga), zinc (Zn), tin (Sn), hafnium (Hf), zirconium (Zr), and aluminum (Al). For example, each of the first active layers (ACT1) may include at least one of zinc oxide (ZnO), zinc-tin oxide (ZTO), indium-zinc oxide (IZO), indium oxide (InO or In₂O₃), titanium oxide (TiO or TiO₂), indium-gallium oxide (IGO), indium-gallium-zinc oxide (IGZO), indium-gallium-tin oxide (IGTO), indium-zinc-tin oxide (IZTO), indium-tin-gallium-zinc oxide (ITGZO), or another oxide semiconductor. The second active layers ACT2 may be formed simultaneously using the same material.

According to some embodiments, the first active layers ACT1 and the second active layers ACT2 may include the same material. For example, the first active layers ACT1 and the second active layers ACT2 may include the same oxide semiconductor.

A second gate insulating layer GI2 may be arranged on the second semiconductor layer. According to some embodiments, the second gate insulating layer (GI2) may have an etched shape to cover only a portion of each of the second active layers ACT2 including the channel region CH, and not to cover other portions (e.g., the source region SR and the drain region DR) of each of the second active layers ACT2. According to some embodiments, the second gate insulating layer GI2 may be arranged entirely on the second buffer layer BFL2 and the second active layers ACT2.

According to some embodiments, when the fifth conductive layer on the second gate insulating layer GI2 includes the second capacitor electrode CPE2, the second gate insulating layer GI2 may also be arranged under the second capacitor electrode CPE2. For example, the second gate insulating layer GI2 may also be arranged between the second buffer layer BFL2 and the second capacitor electrode CPE2.

The second gate insulating layer GI2 may be formed of a single layer or multiple layers of insulating layers including at least one insulating material. For example, the second gate insulating layer GI2 may include at least one inorganic insulating layer including an inorganic insulating material (e.g., silicon oxide, silicon nitride, silicon oxynitride, titanium oxide, aluminum oxide, or other inorganic insulating material).

A fifth conductive layer (e.g., a second gate metal layer) including the second gate electrodes GE2 of the upper transistors UTR may be arranged on the second gate insulating layer GI2. For example, the fifth conductive layer may include the second gate electrodes GE2 of each of the second driving transistor DT2 and the third switching transistor ST3. According to some embodiments, the fifth conductive layer may further include a second capacitor electrode CPE2.

The second gate electrode GE2 of the second driving transistor DT2 may be located on a portion of the second gate insulating layer GI2 covering the channel region CH of the second driving transistor DT2. The second gate electrode GE2 of the third switching transistor ST3 may be arranged on a portion of the second gate insulating layer GI2 covering the channel region CH of the third switching transistor ST3.

The second capacitor electrode CPE2 may overlap the first capacitor electrode CPE1 and/or the third capacitor electrode CPE3. When the first capacitor electrode CPE1 and the second capacitor electrode CPE2 overlap, electrostatic capacitance may be formed between the first capacitor electrode CPE1 and the second capacitor electrode CPE2. When the second capacitor electrode CPE2 and the third capacitor electrode CPE3 overlap, electrostatic capacitance may be formed between the second capacitor electrode CPE2 and the third capacitor electrode CPE3.

At least one capacitor C may be formed by utilizing the electrostatic capacitance formed between the capacitor electrodes CPE. For example, one of the first capacitor C1 and the second capacitor C2 of FIG. 3 or 4 may be formed by utilizing the first capacitor electrode CPE1 and the second capacitor electrode CPE2, and the other of the first capacitor C1 and the second capacitor C2 of FIG. 3 or 4 may be formed by utilizing the second capacitor electrode CPE2 and the third capacitor electrode CPE3. Alternatively, the first capacitor electrode CPE1 and the third capacitor electrode CPE3 may be electrically connected to form the first electrode of the first capacitor C1 or the second capacitor C2, and the second capacitor electrode CPE2 may be formed as the second electrode of the first capacitor C1 or the second capacitor C2. One of the first, second, and third capacitor electrodes CPE3 may be omitted. For example, the conductive patterns arranged on two of the conductive layers included in the panel circuit layer PCL may be divided to form the first capacitor C1 and the second capacitor C2 of FIG. 3 or 4. In addition, the capacitor electrodes CPE may be used to form the capacitor C of the pixel PX in various ways.

The patterns of the fifth conductive layer including the second gate electrodes GE2 may include at least one conductive material. For example, the patterns of the fifth conductive layer may include at least one of the conductive materials of the material of the first conductive layer, or other conductive materials. Each of the patterns of the fifth conductive layer may be formed of a single layer or multiple layers of electrodes, conductive patterns, or wiring.

A second insulating layer INS2 may be arranged on the fifth conductive layer. The second insulating layer INS2 may entirely cover the upper transistors UTR and the second gate insulating layer GI2.

The second insulating layer INS2 may be formed of a single layer or multiple layers of insulating layers including at least one insulating material. For example, the second insulating layer INS2 may include at least one inorganic insulating layer including an inorganic insulating material (e.g., at least one of the inorganic insulating materials of the material of the first buffer layer BFL1, or another inorganic insulating material).

A sixth conductive layer (e.g., a second source-drain metal layer) including connection electrodes CE electrically connected to the upper transistors UTR may be arranged on the second insulating layer INS2. For example, the sixth conductive layer may include upper electrodes CE1B and CE2B of the first and second connection electrodes CE1 and CE2, and a seventh connection electrode CE7. According to some embodiments, the sixth conductive layer may further include the third capacitor electrode CPE3.

The upper electrode CE1B of the first connection electrode CE1 may be electrically connected between the first driving transistor DT1 and the second driving transistor DT2. For example, the upper electrode CE1B of the first connection electrode CE1 may be electrically connected to the lower electrode CE1A of the first connection electrode CE1 through a contact hole penetrating the second insulating layer INS2, the second buffer layer BFL2, and the interlayer insulating layer ILD and may be electrically connected to the source region SR of the first driving transistor DT1 via the lower electrode CE1A of the first connection electrode CE1. Further, the upper electrode CE1B of the first connection electrode CE1 may be electrically connected to the drain region DR of the second driving transistor DT2 through a contact hole penetrating the second insulating layer INS2.

The upper electrode CE2B of the second connection electrode CE2 may be electrically connected between the first bottom electrode BE1 of the first driving transistor DT1 and the source region SR of the second driving transistor DT2. For example, the upper electrode CE2B of the second connection electrode CE2 may be electrically connected to the lower electrode CE2A of the second connection electrode CE2 through a contact hole penetrating the second insulating layer INS2, the second buffer layer BFL2, and the interlayer insulating layer ILD and may be electrically connected to the first bottom electrode BE1 via the lower electrode CE2A of the second connection electrode CE2. Further, the upper electrode CE2B of the second connection electrode CE2 may be electrically connected to the source region SR of the second driving transistor DT2 through a contact hole penetrating the second insulating layer INS2. When the second driving transistor DT2 is the second driving transistor DT2 of FIG. 3, the upper electrode CE2B of the second connection electrode CE2 may be electrically connected to the second bottom electrode BE2 by penetrating the second insulating layer INS2 and the second buffer layer BFL2.

According to some embodiments, the sixth conductive layer may further include a third gate connection electrode electrically connected to the second gate electrode GE2 of the second driving transistor DT2. When the second driving transistor DT2 is the second driving transistor DT2 of FIG. 3 or 4, the third gate connection electrode may be electrically connected to the first node N1.

The seventh connection electrode CE7 may be electrically connected to the source region SR of the third switching transistor ST3. When the third switching transistor ST3 is the sixth transistor T6 of FIG. 3 or FIG. 4, the seventh connection electrode CE7 may be electrically connected to the fourth node N4.

According to some embodiments, the drain region DR of the third switching transistor ST3 may be formed integrally with the second active layer ACT2 of another circuit element. In one example, the drain region DR of the third switching transistor ST3 and the source region SR of the second driving transistor DT2 may be integrally formed. For example, in FIG. 7, the drain region DR of the third switching transistor ST3 and the source region SR of the second driving transistor DT2 are illustrated separated from each other, but the drain region DR of the third switching transistor ST3 and the source region SR of the second driving transistor DT2 may be connected to each other when viewed in a plan view.

According to some embodiments, the sixth conductive layer may further include a fourth gate connection electrode electrically connected to the second gate electrode GE2 of the third switching transistor ST3. When the third switching transistor ST3 is the sixth transistor T6 of FIG. 3 or 4, the fourth gate connection electrode may be electrically connected to the second light emitting control line ECL2.

The patterns of the sixth conductive layer, including the connection electrodes CE and/or the third capacitor electrode CPE3 on the second insulating layer INS2, may include at least one conductive material. For example, the patterns of the sixth conductive layer may include at least one of the conductive materials of the material of the first conductive layer, or other conductive materials. Each of the patterns of the sixth conductive layer may be formed of a single layer or multiple layers of electrodes, conductive patterns, or wiring.

A third insulating layer INS3 may be arranged on the sixth conductive layer. The third insulating layer INS3 may entirely cover the patterns of the second insulating layer INS2 and the sixth conductive layer. The third insulating layer INS3 may entirely cover the circuit elements of the panel circuit layer PCL, including the lower transistors LTR, the upper transistors UTR, and the capacitor electrodes CPE.

The third insulating layer INS3 may be formed of a single layer or multiple layers of insulating layers including at least one insulating material. For example, the third insulating layer INS3 may include at least one organic insulating layer including an organic insulating material (e.g., an acrylic resin, an epoxy resin, a phenolic resin, a polyamide resin, a polyimide resin, or another organic insulating material). The third insulating layer INS3 may alleviate or flatten the steps caused by the circuit elements (e.g., the pixel transistors PXT) and the wirings of the panel circuit layer PCL.

The upper layer of the panel circuit layer PCL may include a fourth conductive layer, a second semiconductor layer, a fifth conductive layer, and a sixth conductive layer sequentially arranged on an interlayer insulating layer ILD. According to some embodiments, the upper layer of the panel circuit layer PCL may further include a seventh conductive layer and a fourth insulating layer INS4 arranged on the third insulating layer INS3.

For example, a seventh conductive layer (e.g., a third source-drain metal layer) including an eighth connection electrode CE8 may be arranged on the third insulating layer INS3. According to some embodiments, the seventh conductive layer may further include at least one power supply line or the like.

The eighth connection electrode CE8 may be electrically connected between circuit elements of the pixel PX and the light emitting element ED. For example, the eighth connection electrode CE8 may be electrically connected to the seventh connection electrode CE7 through a contact hole penetrating the third insulating layer INS3 and may be electrically connected to the third switching transistor ST3 via the seventh connection electrode CE7. Further, the eighth connection electrode CE8 may be electrically connected to the first electrode ET1 of the light emitting element ED.

The patterns of the seventh conductive layer including the eighth connection electrode CE8 may include at least one conductive material. For example, the patterns of the seventh conductive layer may include at least one of the conductive materials of the material of the first conductive layer, or other conductive materials. Each of the patterns of the seventh conductive layer may be formed of a single layer or multiple layers of electrodes, conductive patterns, or wiring.

A fourth insulating layer INS4 may be arranged on the seventh conductive layer. The fourth insulating layer INS4 may entirely cover the patterns of the third insulating layer INS3 and the seventh conductive layer. For example, the fourth insulating layer INS4 may entirely cover the circuit elements and wiring of the panel circuit layer PCL.

The fourth insulating layer INS4 may be formed of a single layer or multiple layers of insulating layers including at least one insulating material. For example, the fourth insulating layer INS4 may be formed of an organic insulating material (e.g., at least one of the organic insulating materials of the material of the third insulating layer INS3, or another organic insulating material). The fourth insulating layer INS4 may alleviate or flatten the step caused by the circuit elements and wiring of the panel circuit layer PCL.

A light emitting element layer LEL may be arranged on the panel circuit layer PCL. For example, the light emitting element layer LEL may be arranged on the fourth insulating layer INS4 and may be located at least in the display area DA.

The light emitting element layer LEL may include the light emitting element ED of each pixel PX. For example, the light emitting element layer LEL may include a pixel defining layer PDL (also referred to as a “bank”) that defines an emission area of each pixel PX and the light emitting element ED located in each emission area. According to some embodiments, the light emitting element layer LEL may further include a spacer SPC arranged on a portion of the pixel defining layer PDL.

Each light emitting element ED may include a first electrode ET1 arranged in each emission area, and a light emitting layer EML and a second electrode ET2 sequentially arranged on the first electrode ET1. The first electrode ET1 of the light emitting element ED may be electrically connected to at least one pixel transistor PXT included in the corresponding pixel PX. For example, the first electrode ET1 of the light emitting element ED may be electrically connected to the eighth connection electrode CE8 through a via hole (or contact hole) penetrating the fourth insulating layer INS4 and may be electrically connected to the third switching transistor (e.g., the sixth transistor T6 of FIG. 3 or 4) via the eighth connection electrode CE8 and the seventh connection electrode CE7.

The first electrode ET1 of the light emitting element ED may be a single-layer or multi-layer electrode including at least one conductive material. According to some embodiments, the display panel 110 may be a front-emitting display panel, and the first electrode ET1 may include a reflective electrode layer having a high reflectivity.

The light emitting layer EML of the light emitting element ED may include a polymer material or a low-molecular material and may emit light of a specific color (or a specific wavelength band). For example, the light emitting layer EML may include at least one light-generating layer that emits red light, green light, blue light, white light, or light of another color. According to some embodiments, the light emitting layer EML may further include at least one intermediate layer (e.g., a hole injection layer, a hole transport layer, an electron transport layer, and/or a charge generation layer, etc.). Light emitted from the light emitting layer EML may contribute to image display.

The light emitting layer EML may be individually formed corresponding to each pixel PX or may be formed as a common layer that is arranged over the entire display area DA. For example, FIG. 7 illustrates embodiments in which the light emitting layer EML is formed around an emission area to overlap the pixel defining layer PDL, but the shape, size, and/or position of the light emitting layer EML may vary depending on the embodiments.

According to some embodiments, the light emitting layer EML may be individually formed in a portion of the pixel area PXA including each emission area and may emit light corresponding to the light emitting wavelength of each pixel PX. For example, the light emitting layer EML included in a red pixel is individually arranged in the emission area of the red pixel and may emit light in a red wavelength band. The light emitting layer EML included in a green pixel may be individually arranged in the emission area of the green pixel and may emit light in a green wavelength band, and the light emitting layer EML included in a blue pixel is individually arranged in the emission area of the blue pixel and may emit light in a blue wavelength band.

According to some embodiments, the light emitting layer EML may be a common layer formed over the entire display area DA and may emit light of a specific wavelength band (e.g., blue light or white light). In this case, a light conversion layer may be arranged on the light emitting element ED of at least one-pixel PX to convert light emitted from the light emitting element ED into light corresponding to the light emitting wavelength of the corresponding pixel PX.

The second electrode ET2 of the light emitting element ED may include a conductive material. According to some embodiments, the second electrode ET2 may be a common layer formed over the entire display area DA in a form that covers the light emitting layer EML and the pixel defining layer PDL. According to some embodiments, the display panel 110 may be a front-emitting display panel, and the second electrode ET2 may include a transparent or translucent electrode layer.

The pixel defining layer PDL may have an opening corresponding to the emission area of each of the pixels PX and may surround the emission area. For example, the pixel defining layer PDL may be formed to cover an edge portion of the first electrode ET1 of the light emitting element ED and may include an opening that exposes the remaining portion of the first electrode ET1. An area where the exposed first electrode ET1 and the light emitting layer EML overlap may be the emission area of each pixel PX. According to some embodiments, the pixel defining layer PDL may include at least one organic insulating layer including an organic insulating material.

The pixel defining layer PDL may be arranged at least in the display area DA. According to some embodiments, the pixel defining layer PDL may also be arranged at least in a portion of the non-display area NDA. As an example, the pixel defining layer PDL may also be arranged in a driving circuit area of the non-display area NDA to cover driving transistors arranged in the driving circuit area.

The spacer SPC may be arranged on a portion of the pixel defining layer PDL. The spacer SPC may include at least one organic insulating layer including an organic insulating material. The spacer SPC may include the same material as the pixel defining layer PDL or may include a different material from the pixel defining layer PDL. The pixel defining layer PDL and the spacer SPC may be sequentially formed through separate mask processes or may be integrally formed using a halftone mask.

An encapsulation layer ENL may be arranged on the light emitting element layer LEL. The encapsulation layer ENL may cover the light emitting element layer LEL in the display area DA and may extend to the non-display area NDA to contact the panel circuit layer PCL. The encapsulation layer ENL may block the penetration of oxygen or moisture into the light emitting element layer LEL and may mitigate electrical and/or physical impacts on the panel circuit layer PCL and the light emitting element layer LEL.

According to some embodiments, the encapsulation layer ENL may include a first encapsulation layer ENL1, a second encapsulation layer ENL2, and a third encapsulation layer ENL3 sequentially arranged on the light emitting element layer LEL. Each of the first encapsulation layer ENL1 and the third encapsulation layer ENL3 may be an inorganic encapsulation layer including an inorganic material. The second encapsulation layer ENL2 may be an organic encapsulation layer including an organic material.

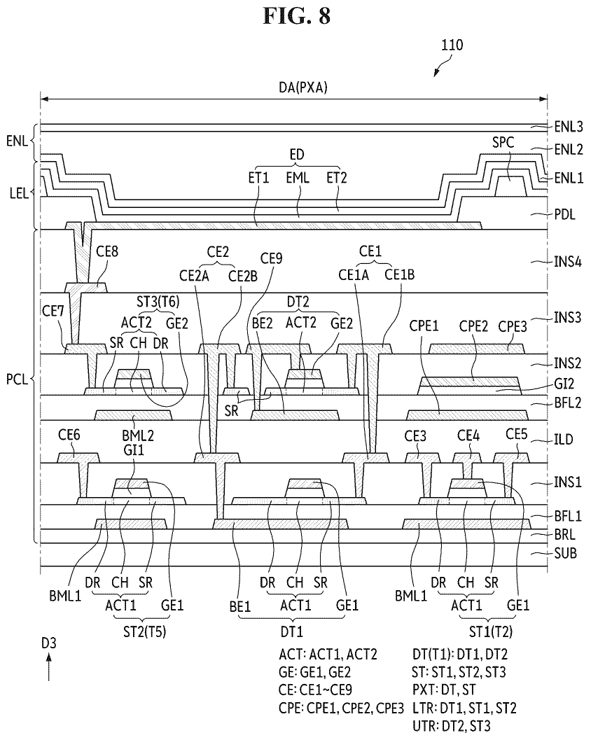

FIG. 8 is a cross-sectional view illustrating a portion of a display panel according to some embodiments. For example, FIG. 8 illustrates a portion of a pixel area PXA included in a display area DA of the display panel 110. Compared to FIG. 7, FIG. 8 illustrates the display panel 110 that further includes a ninth connection electrode CE9.

Each of the embodiments disclosed herein may be implemented alone or in combination with other embodiments. In describing the embodiments below, some redundant descriptions of components identical (or substantially identical or similar) to those described previously may be omitted.

Referring to FIG. 8 in addition to FIGS. 1 to 7, a second bottom electrode BE2 according to some embodiments may be electrically connected to a second gate electrode GE2 of the second driving transistor DT2, as shown in FIGS. 4 and 8. In this case, the display panel 110 may further include a ninth connection electrode CE9 for electrically connecting the second gate electrode GE2 of the second driving transistor DT2 and the second bottom electrode BE2. According to some embodiments, the ninth connection electrode CE9 may be formed as a pattern of the sixth conductive layer arranged on the second insulating layer INS2.

The ninth connection electrode CE9 may be electrically connected to the second gate electrode GE2 of the second driving transistor DT2 through a contact hole penetrating the second insulating layer INS2. Further, the ninth connection electrode CE9 may be electrically connected to the second bottom electrode BE2 of the second driving transistor DT2 through a contact hole penetrating the second insulating layer INS2 and the second buffer layer BFL2.

In the embodiments of FIGS. 4 and 8, the second connection electrode CE2 may be electrically connected between the first bottom electrode BE1 of the first driving transistor DT1 and the source region SR of the second driving transistor DT2. In FIG. 8, the source region SR of the second driving transistor DT2 is illustrated as being separated into two patterns, but the two patterns may be connected to each other when viewed in a plan view. For example, the two patterns may be formed integrally, showing different portions of the source region SR included in the second active layer ACT2 of the second driving transistor DT2.

In the embodiments of FIGS. 7 and 8, at least some of the circuit elements included in the lower layer of the panel circuit layer PCL and the circuit elements included in the upper layer of the panel circuit layer PCL may overlap each other. For example, the second driving transistor DT2 is arranged on at least a portion of the first driving transistor DT1, and the first driving transistor DT1 and the second driving transistor DT2 may overlap each other in the third direction D3. Further, the third switching transistor ST3 is arranged on at least a portion of the second switching transistor ST2, and the second switching transistor ST2 and the third switching transistor ST3 may overlap each other in the third direction D3.

According to some embodiments, the capacitor electrodes CPE may be arranged on an upper portion of the panel circuit layer PCL along with the upper transistors UTR and may overlap at least one lower transistor LTR. For example, the capacitor electrodes CPE are arranged on at least a portion of the first switching transistor ST1, and the first switching transistor ST1 and the capacitor electrodes CPE may overlap each other in the third direction D3.

According to some embodiments, by arranging the circuit elements of the panel circuit layer PCL to overlap each other, the design structure of the panel circuit layer PCL may be relatively improved or optimized. For example, by dividing the pixel transistors PXT into lower and upper layers of the panel circuit layer PCL, the integration of the panel circuit layer PCL may be increased. For example, the first driving transistor DT1 and the second driving transistor DT2 are formed as lower transistors LTR and upper transistors UTR, respectively and may overlap each other. Accordingly, the circuit elements of the pixel PX may be efficiently arranged within each pixel area PXA.

In addition, according to some embodiments, by forming the driving transistor DT of the pixel PX as a dual-structure transistor including the first driving transistor DT1 and the second driving transistor DT2, the channel length and subthreshold slope of the driving transistor DT may be increased. Accordingly, even when the pixel PX is illuminated with a minute driving current Id corresponding to low-grayscale image data, the driving current Id flowing to the pixel PX may be controlled more precisely and/or accurately. Accordingly, according to some embodiments, the low-grayscale expressiveness of the display device 100 may be increased, and the image quality and reliability of the display device 100 may be relatively improved.

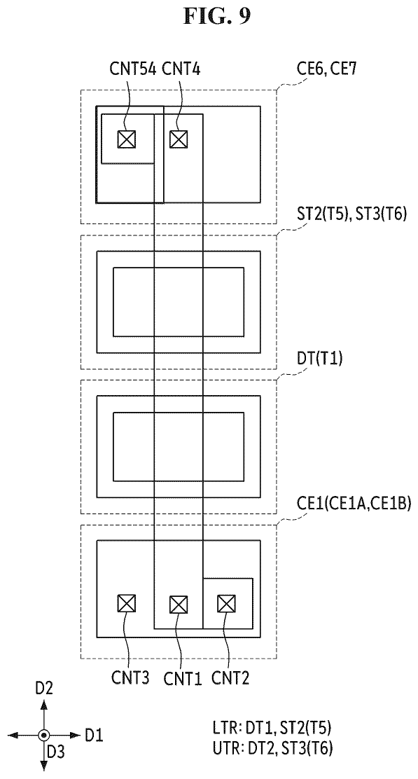

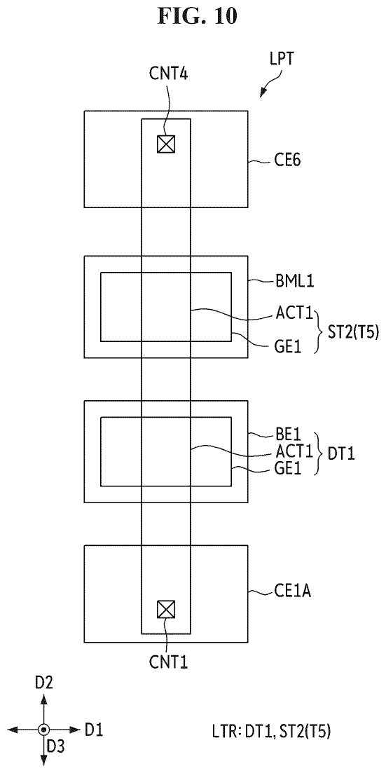

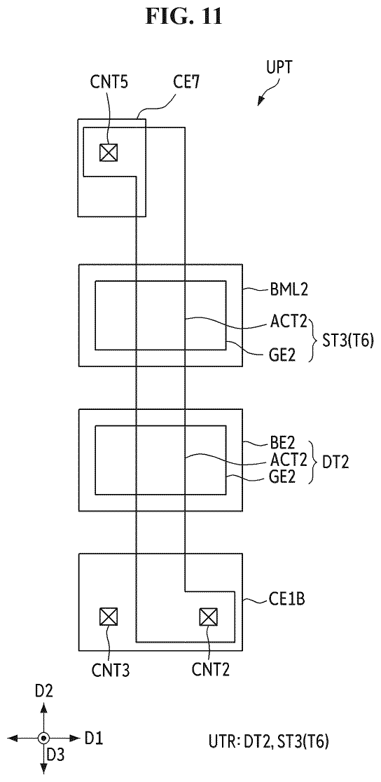

FIG. 9 is a plan view schematically illustrating lower transistors and upper transistors according to some embodiments. FIG. 10 is a plan view illustrating lower patterns including lower transistors of FIG. 9. FIG. 11 is a plan view illustrating upper patterns including upper transistors of FIG. 9.

For example, FIGS. 9 to 11 illustrate embodiments with respect to the arrangement structure of the first and second driving transistors DT1 and DT2 and the second and third switching transistors ST2 and ST3 of FIGS. 3, 4, 7 and 8, showing the general shape and location of the first and second drive transistors DT1 and DT2 and the second and third switching transistors ST2 and ST3.

Referring to FIGS. 9 to 11 in addition to FIGS. 1 to 8, a lower layer of the panel circuit layer PCL may include lower patterns LPT including lower transistors LTR. For example, the lower patterns LPT may include first active layers ACT1 and first gate electrodes GE1 of the lower transistors LTR.

The first active layers ACT1 of the first driving transistor DT1 and the second switching transistor ST2 may be formed integrally. For example, the first active layers ACT1 of the first driving transistor DT1 and the second switching transistor ST2 may be formed as a single semiconductor pattern included in the first semiconductor layer. The first gate electrodes GE1 of the first driving transistor DT1 and the second switching transistor ST2 may be arranged on different portions of the semiconductor pattern and may be separated from each other.

The lower patterns LPT may further include a first bottom electrode BE1 and a first bottom conductive pattern BML1 arranged below the first active layers ACT1. For example, the lower patterns LPT may further include the first bottom electrode BE1 located under the first active layer ACT1 of the first driving transistor DT1, and the first bottom conductive pattern BML1 arranged under the first active layer ACT1 of the second switching transistor ST2.

The lower patterns LPT may further include connection electrodes CE electrically connected to the lower transistors LTR. For example, the lower patterns LPT may include a lower electrode CE1A of a first connection electrode CE1 electrically connected to a portion (e.g., a source region SR) of the first active layer ACT1 included in the first driving transistor DT1 through a first contact hole CNT1, and a sixth connection electrode CE6 electrically connected to a portion (e.g., a drain region DR) of the first active layer ACT1 included in the second switching transistor ST2 through a fourth contact hole CNT4.

The upper layer of the panel circuit layer PCL may include upper patterns UPT including upper transistors UTR. For example, the upper patterns UPT may include second active layers ACT2 and second gate electrodes GE2 of the upper transistors UTR.

The second active layers ACT2 of the second driving transistor DT2 and the third switching transistor ST3 may be formed integrally. For example, the second active layers ACT2 of the second driving transistor DT2 and the third switching transistor ST3 may be formed as a single semiconductor pattern included in the second semiconductor layer. The second gate electrodes GE2 of the second driving transistor DT2 and the third switching transistor ST3 may be arranged on different portions of the semiconductor pattern and may be separated from each other.

According to some embodiments, a ratio of the channel width and a channel length of the first driving transistor DT1 may be substantially the same as a ratio of a channel width and a channel length of the second driving transistor DT2. For example, a ratio of the width and length of the channel region CH of the first driving transistor DT1 (e.g., the region where the first active layer ACT1 and the first gate electrode GE1 of the first driving transistor DT1 overlap) may be the same as a ratio of the width and length of a channel region CH of the second driving transistor DT2 (e.g., the region where the second active layer ACT2 and the second gate electrode GE2 of the second driving transistor DT2 overlap). According to some embodiments, the ratio of the channel width and the channel length of the first driving transistor DT1 may be different from the ratio of the channel width and the channel length of the second driving transistor DT2. By adjusting the ratio of the channel width and the channel length of the first driving transistor DT1 and/or the ratio of the channel width and the channel length of the second driving transistor DT2, the characteristics of the driving transistor DT may be adjusted or optimized.

The upper patterns UPT may further include a second bottom electrode BE2 and a second bottom conductive pattern BML2 arranged below the second active layers ACT2. For example, the upper patterns UPT may further include the second bottom electrode BE2 arranged below the second active layer ACT2 of the second driving transistor DT2, and the second bottom conductive pattern BML2 arranged below the second active layer ACT2 of the third switching transistor ST3.

The upper patterns UPT may further include connection patterns CE electrically connected to the upper transistors UTR. For example, the upper patterns UPT may include an upper electrode CE1B of the first connection electrode CE1 electrically connected to a portion (e.g., a drain region DR) of the second active layer ACT2 included in the second driving transistor DT2 through a second contact hole CNT2, an electrically connected to a lower electrode CE1A of the first connection electrode CE1 through a third contact hole CNT3, and the seventh connection electrode CE7 electrically connected to a portion (e.g., a source region SR) of the second active layer ACT2 included in the third switching transistor ST3 through a fifth contact hole CNT5.

Each of the other pixel transistors PXT (e.g., the second, third and fourth transistors T2, T3, and T4 of FIG. 3 or 4) may be formed as a lower transistor LTR or as an upper transistor UTR. For example, a plurality of pixel transistors PXT and at least one capacitor C included in each pixel PX may be appropriately divided and arranged in a lower layer and an upper layer of the panel circuit layer PCL. The circuit elements arranged in the lower layer of the panel circuit layer PCL and circuit elements arranged in the upper layer of the panel circuit layer PCL may overlap each other.

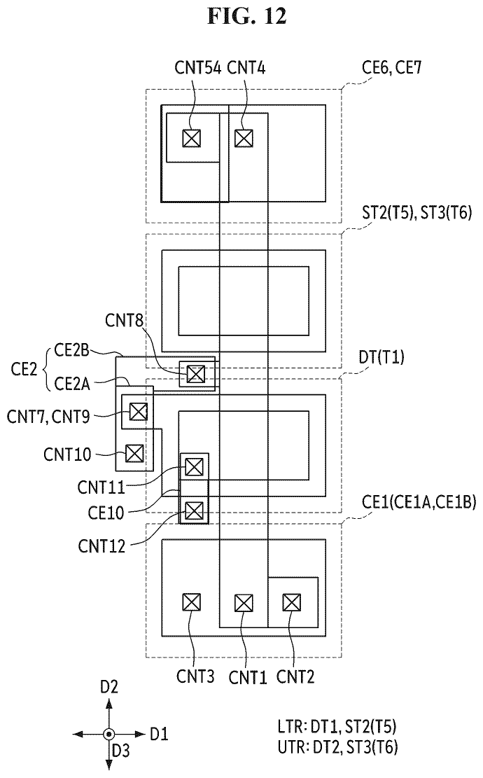

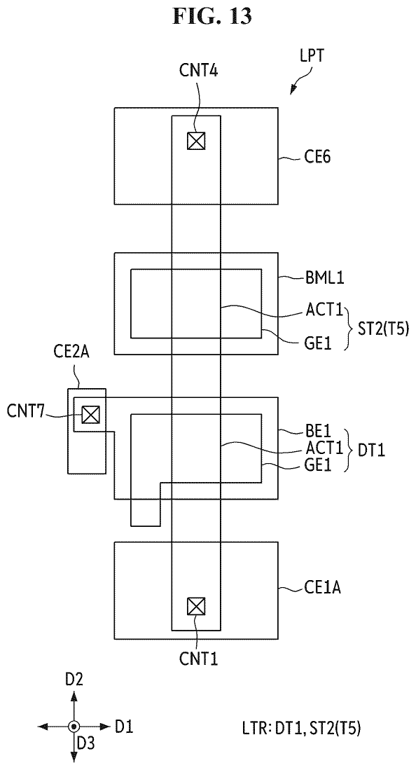

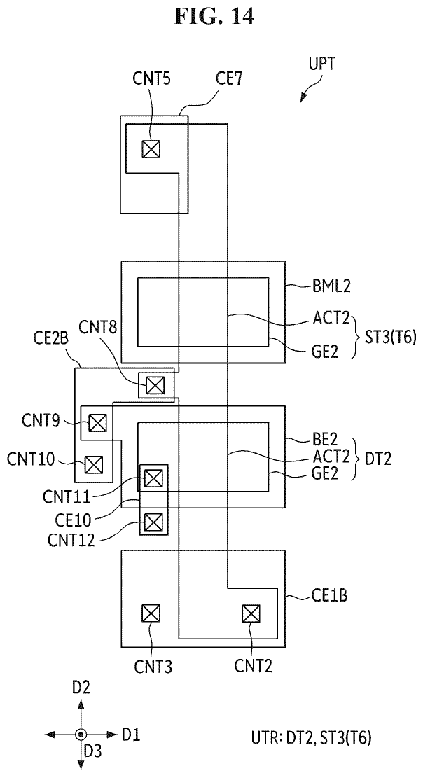

FIG. 12 is a plan view schematically illustrating lower transistors and upper transistors according to some embodiments. FIG. 13 is a plan view illustrating lower patterns including lower transistors of FIG. 12. FIG. 14 is a plan view illustrating upper patterns including upper transistors of FIG. 12. Compared with FIGS. 9 to 11, FIGS. 12 to 14 further illustrate the second connection electrode CE2 and the tenth connection electrode CE10 connected to the first and second driving transistors DT1 and DT2.

Referring to FIGS. 12 to 14 in addition to FIGS. 1 to 11, the lower patterns LPT may further include the lower electrode CE2A of the second connection electrode CE2, and the upper patterns UPT may further include the upper electrode CE2B of the second connection electrode CE2, and the tenth connection electrode CE10.

The lower electrode CE2A of the second connection electrode CE2 may be electrically connected to the first bottom electrode BE1 of the first driving transistor DT1 through a seventh contact hole CNT7.

The upper electrode CE2B of the second connection electrode CE2 may be electrically connected to a portion (e.g., a source region SR) of the second active layer ACT2 included in the second driving transistor DT2 through an eighth contact hole CNT8 and may be electrically connected to the lower electrode CE2A of the second connection electrode CE2 through a tenth contact hole CNT10. When the first driving transistor DT1 and the second driving transistor DT2 are the first driving transistor DT1 and the second driving transistor DT2 of FIG. 3 or 4, the upper electrode CE2B of the second connection electrode CE2 may be electrically connected to the third node N3.

When the second driving transistor DT2 is the second driving transistor DT2 of FIG. 3 and FIG. 7, the second connection electrode CE2 may also be connected to the second bottom electrode BE2 of the second driving transistor DT2. For example, the upper electrode CE2B of the second connection electrode CE2 may be electrically connected to the second bottom electrode BE2 through a ninth contact hole CNT9.

The tenth connection electrode CE10 may be electrically connected to the first gate electrode GE1 and the second gate electrode GE2. For example, the tenth connection electrode CE10 may be electrically connected to the second gate electrode GE2 of the second driving transistor DT2 through an eleventh contact hole CNT11 and to the first gate electrode GE1 of the first driving transistor DT1 through a twelfth contact hole CNT12. When the first driving transistor DT1 and the second driving transistor DT2 are the first driving transistor DT1 and the second driving transistor DT2 of FIG. 3 or 4, the tenth connection electrode CE10 may be electrically connected to the first node N1. In FIGS. 12 to 14, the tenth connection electrode CE10 is illustrated as having a size sufficient to connect the first gate electrode GE1 of the first driving transistor DT1 and the second gate electrode GE2 of the second driving transistor DT2, but the shape, size, and/or position of the tenth connection electrode CE10 may vary depending on the embodiments. For example, the tenth connection electrode CE10 may extend to an area where the first capacitor C1 of FIG. 3 or 4 is formed and may be formed integrally with one capacitor electrode CPE included in the first capacitor C1.

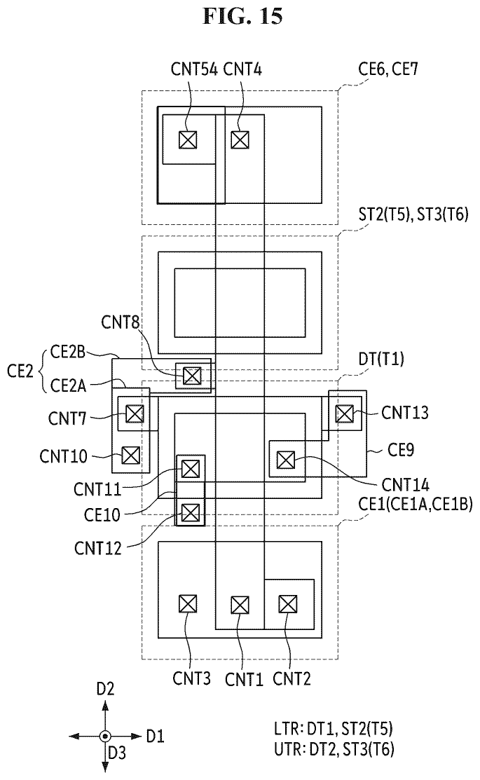

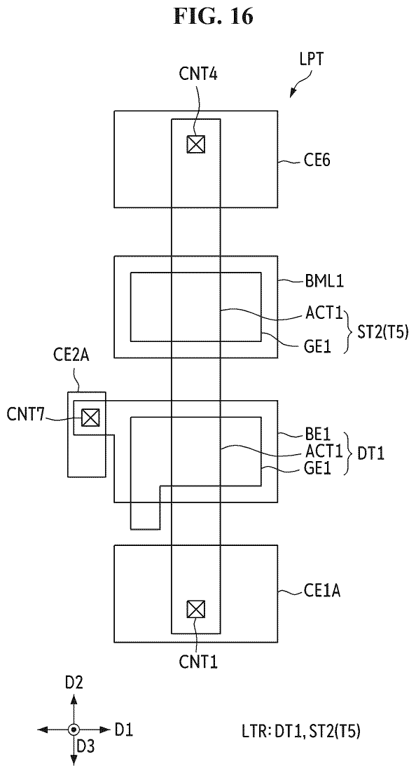

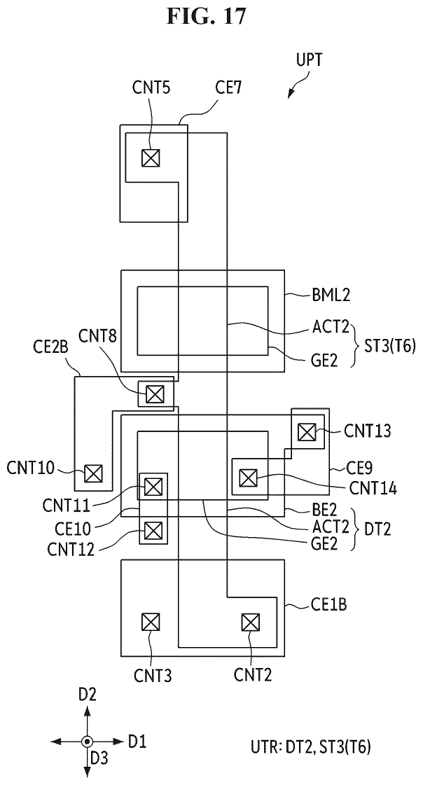

FIG. 15 is a plan view schematically illustrating lower transistors and upper transistors according to some embodiments. FIG. 16 is a plan view illustrating lower patterns including lower transistors of FIG. 15. FIG. 17 is a plan view illustrating upper patterns including upper transistors of FIG. 15.

Compared with FIGS. 9 to 11, FIGS. 15 to 17 further illustrate the second connection electrode CE2, the ninth connection electrode CE9, and the tenth connection electrode CE10 connected to the first and second driving transistors DT1 and DT2. Compared with FIGS. 12 to 14, FIGS. 15 to 17 further illustrate the ninth connection electrode CE9, and the structure of the second connection electrode CE2 is slightly different.

Referring to FIGS. 15 to 17 in addition to FIGS. 1 to 14, the second connection electrode CE2 may electrically connect the first bottom electrode BE1 of the first driving transistor DT1 and the source region SR of the second driving transistor DT2. When the second driving transistor DT2 is the second driving transistor DT2 of FIG. 4 and FIG. 8, the second connection electrode CE2 may not be connected to the second bottom electrode BE2 of the second driving transistor DT2. For example, the ninth contact hole CNT9 of FIGS. 12 to 14 may be omitted.

The ninth connection electrode CE9 may electrically connect the second bottom electrode BE2 and the second gate electrode GE2 of the second driving transistor DT2. For example, the ninth connection electrode CE9 may be electrically connected to the second bottom electrode BE2 of the second driving transistor DT2 through a thirteenth contact hole CNT13 and to the second gate electrode GE2 of the second driving transistor DT2 through a fourteenth contact hole CNT14.

As in the embodiments of FIGS. 9 to 17, circuit elements of each pixel PX may be appropriately connected in a form that matches the circuit configuration of each pixel PX by utilizing connection electrodes CE of various shapes, numbers, and/or sizes.

As described above, according to some embodiments, the driving transistor DT of the pixel PX may be formed as a dual-structured transistor including the first driving transistor DT1 and the second driving transistor DT2 that overlap each other. As a result, the area occupied by the driving transistor DT in each pixel area PXA may be reduced while increasing the channel length of the driving transistor DT and securing a subthreshold slope. Furthermore, according to the embodiments described above, the circuit elements of the pixel PX including the driving transistor DT may be efficiently arranged in each pixel area PXA, and the number of contact holes may be reduced or minimized. As a result, the layout integration of the panel circuit layer PCL may be increased, and the design structure of the panel circuit layer PCL may be relatively improved.

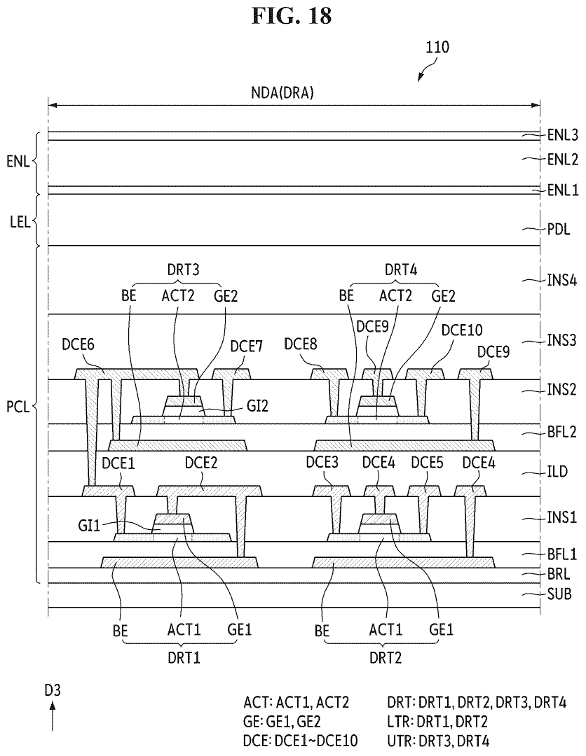

FIG. 18 is a cross-sectional view illustrating a portion of a display panel according to some embodiments. For example, FIG. 18 illustrates a portion of the driving circuit area DRA included in a non-display area NDA of the display panel 110.

Referring to FIG. 18 in addition to FIGS. 1 to 17, circuit elements included in a gate driver 120 may be arranged in the driving circuit area DRA of the non-display area NDA. For example, driving transistors DRT included in the gate driver 120, and driving portion capacitors electrically connected to the driving transistors DRT may be arranged in the driving circuit area DRA.

The gate driver 120 may include at least one gate signal generating portion that generates at least one type of gate signal GS. For example, the gate driver 120 may include a plurality of gate signal generating portions that generate a plurality of gate signals GS supplied to each pixel PX. Each gate signal generation portion may include stages STG for sequentially outputting each gate signal GS.

Each stage STG may include a plurality of circuit elements. For example, each stage STG may include a plurality of control transistors and/or driving capacitors included in the control circuit NC of FIG. 6. Further, each stage STG may include buffer transistors (e.g., first and second pull-up transistors PUT1 and PUT2 and first and second pull-down transistors PDT1 and PDT2) included in the first output circuit OB1 and the second output circuit OB2 of FIG. 6.

According to some embodiments, the driver transistors DRT and the pixel transistors PXT may be formed simultaneously using the same material. For example, some of the driver transistors DRT may be formed as lower transistors LTR along with the first driving transistor DT1 of the pixel PX, and other of the driver transistors DRT may be formed as upper transistors UTR along with the second driving transistor DT2 of the pixel PX. At least some of the lower transistors LTR and at least some of the upper transistors UTR arranged in the driving circuit area DRA may be arranged to overlap each other.

According to some embodiments, the control transistors and buffer transistors included in each stage STG may be arranged to overlap each other by dividing and arranging them in the lower and upper layers of the panel circuit layer PCL. According to some embodiments, the driver transistors DRT included in different stages STG may be arranged to overlap each other by dividing and arranging them in the lower and upper layers of the panel circuit layer PCL. According to some embodiments, the driver transistors DRT of each of the gate signal generating portions that generate different types of gate signals GS may be arranged in the lower and upper layers of the panel circuit layer PCL, respectively, so that a plurality of gate signal generating portions may be arranged to overlap each other. In addition, the driver transistors DRT of the gate driver 120 may be appropriately divided and arranged in the lower and upper layers of the panel circuit layer PCL in various forms.

FIG. 18 illustrates the first driver transistor DRT1 and the second driver transistor DRT2 formed of lower transistors LTR, and the third driver transistor DRT3 and the fourth driver transistor DRT4 formed of upper transistors UTR among the driver transistors DRT that may be included in the gate driver 120. According to some embodiments, the first driver transistor DRT1 may overlap the third driver transistor DRT3, and the second driver transistor DRT2 may overlap the fourth driver transistor DRT4.

Each of the first driver transistor DRT1 and the second driver transistor DRT2 may include a first active layer ACT1 arranged on a first buffer layer BFL1, and a first gate electrode GE1 arranged on a portion of the first active layer ACT1 (e.g., a channel region overlapping with each first gate electrode GE1). A first gate insulating layer GI1 may be arranged between the first active layer ACT1 and the first gate electrode GE1 of each of the first driver transistor DRT1 and the second driver transistor DRT2.

According to some embodiments, a bottom electrode BE may be arranged below the first active layer ACT1 of each of the first driver transistor DRT1 and the second driver transistor DRT2. Further, the bottom electrode BE of each of the first driver transistor DRT1 and the second driver transistor DRT2 may be electrically connected to the first active layer ACT1 or the first gate electrode GE1 of each of the first driver transistor DRT1 and the second driver transistor DRT2 and may be utilized to adjust characteristics of each of the first driver transistor DRT1 and the second driver transistor DRT2. For example, the bottom electrode BE of each of the first driver transistor DRT1 and the second driver transistor DRT2 may be electrically connected to the first gate electrode GE1 of each of the first driver transistor DRT1 and the second driver transistor DRT1. Accordingly, the operating characteristics (e.g., the response speed and/or on-state current) of each of the first driver transistor DRT1 and the second driver transistor DRT2 may be relatively improved.

Each of the third driver transistor DRT3 and the fourth driver transistor DRT4 may include a second active layer ACT2 arranged on a second buffer layer BFL2, and a second gate electrode GE2 arranged on a portion of the second active layer ACT2 (e.g., a channel region overlapping with each second gate electrode GE2). A second gate insulating layer GI2 may be arranged between the second active layer ACT2 and the second gate electrode GE2 of each of the third driver transistor DRT3 and the fourth driver transistor DRT4.

According to some embodiments, the bottom electrode BE may be arranged under the second active layer ACT2 of each of the third driver transistor DRT3 and the fourth driver transistor DRT4. Further, the bottom electrode BE of each of the third driver transistor DRT3 and the fourth driver transistor DRT4 may be electrically connected to the second active layer ACT2 or the second gate electrode GE2 of each of the third driver transistor DRT3 and the fourth driver transistor DRT4 and may be utilized to adjust the characteristics of each of the third driver transistor DRT3 and the fourth driver transistor DRT4. For example, the bottom electrode BE of each of the third driver transistor DRT3 and the fourth driver transistor DRT4 may be electrically connected to the second gate electrode GE2 of each of the third driver transistor DRT3 and the fourth driver transistor DRT4. Accordingly, the operating characteristics (e.g., the response speed and/or on current) of each of the third driver transistor DRT3 and the fourth driver transistor DRT4 may be relatively improved.

In the driving circuit area DRA, connection electrodes DCE electrically connected to the driver transistors DRT may be further arranged. For example, the connection electrodes DCE may be used to appropriately connect the driver transistors DRT according to the circuit configuration of the gate driver 120.

FIG. 18 illustrates first to tenth connection electrodes DCE1 to DCE10 as an example of the connection electrodes DCE of the driving circuit area DRA. The first to fifth connection electrodes DCE1 to DCE5 may be arranged on the first insulating layer INS1. The sixth to tenth connection electrodes DCE6 to DCE10 may be arranged on the second insulating layer INS2.

The first connection electrode DCE1 may be electrically connected to the first driver transistor DRT1. For example, the first connection electrode DCE1 may be electrically connected to a portion (e.g., one of the source region and the drain region) of the first active layer ACT1 included in the first driver transistor DRT1. The first connection electrode DCE1 may electrically connect the first driver transistor DRT1 to another circuit element (e.g., the third driver transistor DRT3) or wiring. When the portion of the first active layer ACT1 included in the first driver transistor DRT1 is integrally connected to the first active layer ACT1 of another lower transistor LTR, the first connection electrode DCE1 may be omitted. According to some embodiments, another portion (e.g., another one of the source region and the drain region) of the first active layer ACT1 included in the first driver transistor DRT1 may be integrally connected to the first active layer ACT1 of another lower transistor LTR (e.g., the second driver transistor DRT2).

The second connection electrode DCE2 may be electrically connected to the first driver transistor DRT1. For example, the second connection electrode DCE2 may connect the first gate electrode GE1 and the bottom electrode BE of the first driver transistor DRT1. The second connection electrode DCE2 may be further connected to another circuit element or wiring.

The third connection electrode DCE3 may be electrically connected to the second driver transistor DRT2. For example, the third connection electrode DCE3 may be electrically connected to a portion (e.g., one of the source region and the drain region) of the first active layer ACT1 included in the second driver transistor DRT2. The third connection electrode DCE3 may electrically connect the second driver transistor DRT2 to another circuit element or wiring. If the portion of the first active layer ACT1 included in the second driver transistor DRT2 is integrally connected to the first active layer ACT1 of another lower transistor LTR, the third connection electrode DCE3 may be omitted.

The fourth connection electrode DCE4 may be electrically connected to the second driver transistor DRT2. For example, the fourth connection electrode DCE4 may connect the first gate electrode GE1 and the bottom electrode BE of the second driver transistor DRT2. In FIG. 18, the fourth connection electrode DCE4 is illustrated as being divided into two patterns, but the two patterns may be connected to different portions of the fourth connection electrode DCE4 when viewed in a plan view. The fourth connection electrode DCE4 may be further connected to other circuit elements or wiring.

The fifth connection electrode DCE5 may be electrically connected to the second driver transistor DRT2. For example, the fifth connection electrode DCE5 may be electrically connected to another portion (e.g., another one of the source region and the drain region) of the first active layer ACT1 included in the second driver transistor DRT2. The fifth connection electrode DCE5 may electrically connect the second driver transistor DRT2 to another circuit element or wiring. If the other portion of the first active layer ACT1 included in the second driver transistor DRT2 is integrally connected to the first active layer ACT1 of another lower transistor LTR, the fifth connection electrode DCE5 may be omitted.

The sixth connection electrode DCE6 may be electrically connected to the third driver transistor DRT3. For example, the sixth connection electrode DCE6 may connect the second gate electrode GE2 and the bottom electrode BE of the third driver transistor DRT3. According to some embodiments, the sixth connection electrode DCE6 may be further connected to another circuit element or wiring. For example, the sixth connection electrode DCE6 may be electrically connected to the first connection electrode DCE1. In this case, the second gate electrode GE2 and the bottom electrode BE of the third driver transistor DRT3 may be electrically connected to the first active layer ACT1 of the first driver transistor DRT1.

The seventh connection electrode DCE7 may be electrically connected to the third driver transistor DRT3. For example, the seventh connection electrode DCE7 may be electrically connected to a portion (e.g., one of the source region and the drain region) of the first active layer ACT1 included in the third driver transistor DRT3. The seventh connection electrode DCE7 may electrically connect the third driver transistor DRT3 to another circuit element or wiring. If the portion of the first active layer ACT1 included in the third driver transistor DRT3 is integrally connected to the second active layer ACT2 of another upper transistor UTR, the seventh connection electrode DCE7 may be omitted. According to some embodiments, another portion (e.g., another one of the source region and the drain region) of the second active layer ACT2 included in the third driver transistor DRT3 may be integrally connected to the second active layer ACT2 of another lower transistor LTR (e.g., the fourth driver transistor DRT4).

The eighth connection electrode DCE8 may be electrically connected to the fourth driver transistor DRT4. For example, the eighth connection electrode DCE8 may be electrically connected to a portion (e.g., one of the source region and the drain region) of the second active layer ACT2 included in the fourth driver transistor DRT4. The eighth connection electrode DCE8 may electrically connect the fourth driver transistor DRT4 to another circuit element or wiring. If a portion of the second active layer ACT2 included in the fourth driver transistor DRT4 is integrally connected to the second active layer ACT2 of another lower transistor LTR, the eighth connection electrode DCE8 may be omitted.

The ninth connection electrode DCE9 may be electrically connected to the fourth driver transistor DRT4. For example, the ninth connection electrode DCE9 may connect the second gate electrode GE2 and the bottom electrode BE of the fourth driver transistor DRT4. In FIG. 18, the ninth connection electrode DCE9 is illustrated as being divided into two patterns, but the two patterns may be connected when viewed on a plane as different portions of the ninth connection electrode DCE9. The ninth connection electrode DCE9 may be further connected to other circuit elements or wiring, etc.

The tenth connection electrode DCE10 may be electrically connected to the fourth driver transistor DRT4. For example, the tenth connection electrode DCE10 may be electrically connected to another portion (e.g., another one of the source region and the drain region) of the second active layer ACT2 included in the fourth driver transistor DRT4. The tenth connection electrode DCE10 may electrically connect the fourth driver transistor DRT4 to another circuit element or wiring. If the other portion of the second active layer ACT2 included in the fourth driver transistor DRT4 is integrally connected to the second active layer ACT2 of another lower transistor LTR, the tenth connection electrode DCE10 may be omitted.

As described above, the gate driver 120 according to some embodiments may include lower transistors LTR and upper transistors UTR that are arranged to overlap each other in the driving circuit area DRA. Accordingly, the area occupied by the gate driver 120 in the non-display area NDA (e.g., the area of the driving circuit area DRA) may be reduced, and the non-display area NDA may be reduced or minimized.

The display device 100 according to at least one of the above-described embodiments may be applied to various electronic devices. The electronic device according to some embodiments includes the above-described display device 100 (or a display module including the display panel 110 according to at least one embodiment) and may further include a module or device having other additional functions in addition to the display device 100.

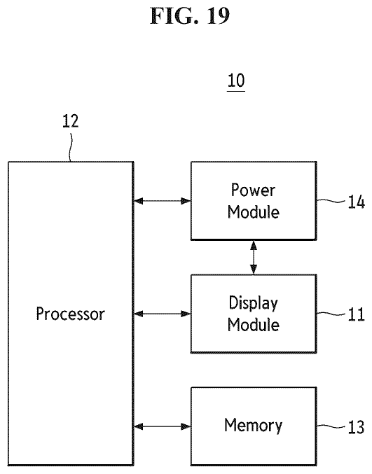

FIG. 19 is a block diagram of an electronic device according to some embodiments.

Referring to FIG. 19, an electronic device 10 according to some embodiments may include a display module 11, a processor 12, a memory 13, and a power module 14.

The electronic device 10 may output various information in the form of an image through the display module 11. For example, when the processor 12 executes an application stored in the memory 13, the image information provided by the application may be provided to the user through the display module 11.

The display module 11 may include a display panel for displaying an image. As an example, the display module 11 may include a display panel 110 according to at least one of the embodiments described with reference to FIGS. 1 to 18.

The processor 12 may include at least one of a central processing unit (CPU), an application processor (AP), a graphic processing unit (GPU), a communication processor (CP), an image signal processor (ISP), or a controller.

The memory 15 may store data information necessary for the operation of the processor 12 or the display module 11. For example, the memory 15 may store image data signals and/or input control signals.

The processor 12 may control the display module 11 using the information stored in the memory 15. The processor 12 may transmit the image data signals and/or input control signals stored in the memory 15 to the display module 11. For example, when the processor 12 executes an application stored in the memory 15, the image data signals and/or input control signals are transmitted to the display module 11, and the display module 11 may process the received signals to output image information through the display screen.

The power module 14 may include a power supply module such as a power adapter or a battery device, and a power conversion module that converts power supplied by the power supply module to generate power necessary for the operation of the electronic device 10.

At least one of the components of the electronic device 10 described above may be included in the display device 100. Further, some of the individual modules functionally included in one module may be included in the display device 100 and others may be provided separately from the display device 100. For example, the display device 100 may include the display module 11, and the processor 12, the memory 13, and the power module 14 may be provided in the form of other devices within the electronic device 10 rather than the display device 100.

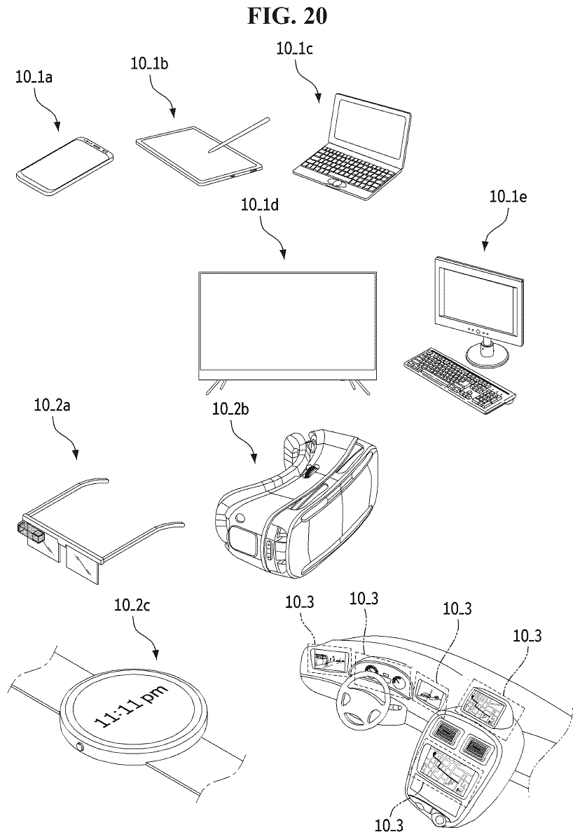

FIG. 20 is schematic diagrams of an electronic device according to various embodiments.

Referring to FIG. 20, various electronic devices to which the display device 100 according to the embodiments is applied may include not only image display electronic devices such as a smart phone 10_1a, a tablet PC 10_1b, a laptop 10_1c, a TV 10_1d, and a desk monitor 10_1e, but also wearable electronic devices including display modules such as smart glasses 10_2a, a head-mounted display 10_2b, and a smart watch 10_2c, and vehicle electronic devices 10_3 including display modules such as a CID (Center Information Display) and a room mirror display arranged on a dashboard, center fascia, and dashboard of a car.

As described above, the display device 100 and the electronic device 10 according to some embodiments may include a driving transistor DT including a first driving transistor DT1 and a second driving transistor DT2 arranged to overlap each other on a substrate SUB. According to embodiments, the channel length and subthreshold slope of the driving transistor DT are increased and/or secured to relatively improve the operating characteristics of the driving transistor DT, and the driving current Id flowing to the pixel PX may be controlled more precisely. Accordingly, the low-grayscale expressiveness of the display device 100 and the electronic device 10 may be increased, the image quality may be relatively improved, and the design structure of the panel circuit layer PCL may be relatively improved.

In concluding the detailed description, those skilled in the art will appreciate that many variations and modifications can be made to the embodiments without departing from the spirit and scope of embodiments according to the present disclosure. Therefore, the disclosed embodiments of the invention are used in a generic and descriptive sense only and not for purposes of limitation.

What is claimed is:

1. A display device comprising:
a substrate;
a first driving transistor on the substrate, including a first active layer and a first gate electrode;
a first insulating layer on the first driving transistor;
a second driving transistor on the first insulating layer, including a second active layer electrically connected to the first active layer and a second gate electrode electrically connected to the first gate electrode;
a second insulating layer on the second driving transistor; and
a light emitting element on the second insulating layer.

2. The display device of claim 1, wherein the first active layer and the second active layer overlap each other in a thickness direction of the substrate.

3. The display device of claim 1, wherein the first driving transistor further includes a first bottom electrode between the substrate and the first active layer and overlapping a channel region of the first active layer,
wherein the first bottom electrode is electrically connected to a source region of the second active layer.

4. The display device of claim 1, wherein the second driving transistor further includes a second bottom electrode between the first insulating layer and the second active layer and overlapping a channel region of the second active layer,
wherein the second bottom electrode is electrically connected to a source region of the second active layer.

5. The display device of claim 1, wherein the second driving transistor further includes a second bottom electrode between the first insulating layer and the second active layer and overlapping a channel region of the second active layer,
wherein the second bottom electrode is electrically connected to the second gate electrode.

6. The display device of claim 1, further comprising a connection electrode electrically connecting the first active layer and the second active layer.

7. The display device of claim 6, wherein the connection electrode comprises,
a lower electrode on the first insulating layer and electrically connected to a source region of the first active layer; and
an upper electrode on the second insulating layer and electrically connected to a drain region of the second active layer and the lower electrode.

8. The display device of claim 1, further comprising a first switching transistor on the substrate, and comprising an active layer on a same layer as the first active layer and a gate electrode in a same layer as the first gate electrode.

9. The display device of claim 8, further comprising capacitor electrodes on the first switching transistor and overlapping each other.

10. The display device of claim 1, further comprising a second switching transistor on the substrate, and including an active layer in a same layer as the first active layer and a gate electrode in a same layer as the first gate electrode; and
a third switching transistor on the first insulating layer, and including an active layer in a same layer as the second active layer and a gate electrode in a same layer as the second gate electrode,
wherein the second switching transistor and the third switching transistor overlap each other in a thickness direction of the substrate.

11. The display device of claim 1, wherein each of the first active layer and the second active layer includes an oxide semiconductor.

12. The display device of claim 1, further comprising a pixel in a display area on the substrate, and including the first driving transistor, the second driving transistor, and the light emitting element; and
a gate driver in a non-display area on the substrate, and electrically connected to the pixel.

13. The display device of claim 12, wherein the gate driver comprises,
a lower transistor including an active layer in a same layer as the first active layer and a gate electrode in a same layer as the first gate electrode; and
an upper transistor including an active layer in a same layer as the second active layer and a gate electrode in a same layer as the second gate electrode.

14. The display device of claim 13, wherein the lower transistor and the upper transistor overlap each other in a thickness direction of the substrate.

15. An electronic device comprising:
a display module including a display panel; and
a processor configured to transmit an image data signal to the display module,
wherein the display panel comprises:
a substrate;
a first driving transistor on the substrate, including a first active layer and a first gate electrode;
a first insulating layer on the first driving transistor;
a second driving transistor on the first insulating layer, including a second active layer electrically connected to the first active layer and a second gate electrode electrically connected to the first gate electrode;
a second insulating layer on the second driving transistor; and
a light emitting element on the second insulating layer.

16. The electronic device of claim 15, wherein the first active layer and the second active layer overlap each other in a thickness direction of the substrate.

17. The electronic device of claim 15, wherein the first driving transistor further includes a first bottom electrode between the substrate and the first active layer and overlapping a channel region of the first active layer,
wherein the first bottom electrode is electrically connected to a source region of the second active layer.

18. The electronic device of claim 15, wherein the second driving transistor further includes a second bottom electrode between the first insulating layer and the second active layer and overlapping a channel region of the second active layer,
wherein the second bottom electrode is electrically connected to a source region of the second active layer or to the second gate electrode.

19. The electronic device of claim 15, wherein the display panel further comprises,
a first switching transistor on the substrate, including an active layer in a same layer as the first active layer and a gate electrode in a same layer as the first gate electrode; and
capacitor electrodes on the first switching transistor and overlapping each other.

20. The electronic device of claim 15, wherein the display panel further comprises,
a second switching transistor on the substrate, and including an active layer in a same layer as the first active layer and a gate electrode in a same layer as the first gate electrode; and
a third switching transistor on the first insulating layer, and including an active layer in a same layer as the second active layer and a gate electrode in a same layer as the second gate electrode,
wherein the second switching transistor and the third switching transistor overlap each other in a thickness direction of the substrate.
